(19) United States
(12) Patent Application Publication
(10) Pub. No.: US 2026/0068301 A1
(43) Pub. Date: Mar. 5, 2026

(54) SEMICONDUCTOR DEVICE

(71) Applicant: SAMSUNG ELECTRONICS CO., LTD., Suwon-si (KR)

(72) Inventors: SUYOUNG BAE, Suwon-si (KR); Jaeyeol Song, Suwon-si (KR); Jeonghyuk Yim, Suwon-si (KR)

(73) Assignee: SAMSUNG ELECTRONICS CO., LTD., Suwon-si (KR)

(21) Appl. No.: 19/178,000

(22) Filed: Apr. 14, 2025

(30) Foreign Application Priority Data
Sep. 4, 2024 (KR) 10-2024-0119953

(51) Int. Cl. H10D 84/85; H10D 30/00; H10D 30/01; H10D 30/43; H10D 62/10; H10D 62/13; H10D 64/23; H10D 64/27; H10D 64/66; H10D 84/01

(52) U.S. Cl. CPC H10D 84/851; H10D 30/43; H10D 30/503; H10D 30/506; H10D 62/121; H10D 62/151; H10D 64/256; H10D 64/518; H10D 64/666; H10D 84/856; H10D 30/014; H10D 30/0191; H10D 84/0177

(57) ABSTRACT

A semiconductor device is provided. The semiconductor device includes: a first active pattern on a first active region of a substrate; a second active pattern on a second active region of the substrate, wherein the first active region is spaced apart from the second active region in a first direction; a first channel pattern that includes first semiconductor patterns that are spaced apart from each other and vertically stacked on the first active pattern; and a gate electrode on the first channel pattern. The gate electrode includes: first metal patterns on the first semiconductor patterns on the first active region; and a gap-fill pattern between the first metal patterns on the first active region. A maximum width in the first direction of the gap-fill pattern is less than a maximum width in the first direction of the first metal patterns.

### CROSS-REFERENCE TO RELATED APPLICATION

This application claims priority to Korean Patent Application No. 10-2024-0119953, filed on Sep. 4, 2024, in the Korean Intellectual Property Office, the disclosure of which is incorporated herein by reference in its entirety.

### BACKGROUND

The present disclosure relates to a semiconductor device, and more particularly, to a semiconductor device including a field effect transistor and a method of fabricating the same.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

One or more embodiments provide a semiconductor device having increased reliability and improved electrical properties.

One or more embodiments provide a method of fabricating a semiconductor device having increased reliability and improved electrical properties.

According to an aspect of an embodiment, a semiconductor device, includes: a first active pattern on a first active region of a substrate; a second active pattern on a second active region of the substrate, wherein the first active region is spaced apart from the second active region in a first direction; a first channel pattern that includes a plurality of first semiconductor patterns that are spaced apart from each other and vertically stacked on the first active pattern; and a gate electrode on the first channel pattern. The gate electrode includes: a plurality of first metal patterns on the plurality of first semiconductor patterns on the first active region; and a gap-fill pattern between the plurality of first metal patterns on the first active region. A maximum width in the first direction of the gap-fill pattern is less than a maximum width in the first direction of the plurality of first metal patterns.

According to another aspect of an embodiment, a semiconductor device includes: a first active pattern on a first active region of a substrate; a second active pattern on a second active region of the substrate, wherein the first active region is spaced apart from the second active region in a first direction; a first channel pattern including a plurality of first semiconductor patterns that are spaced apart from each other and vertically stacked on the first active pattern; a second channel pattern that includes a plurality of second semiconductor patterns that are spaced apart from each other and vertically stacked on the second active pattern; and a gate electrode on the first channel pattern and the second channel pattern. The gate electrode includes: a plurality of first metal patterns on the first active region, the plurality of first metal patterns being on the plurality of first semiconductor patterns and spaced apart from each other in a vertical direction; a plurality of gap-fill patterns in first inner regions between the plurality of first metal patterns on the first active region; and a second metal pattern that covers sidewalls of the plurality of first metal patterns on the first active region and is in second inner regions between the plurality of second semiconductor patterns on the second active region.

According to another aspect of an embodiment, a semiconductor device, includes: a first active pattern on a first active region of a substrate; a second active pattern on a second active region of the substrate, wherein the first active region is spaced apart from the second active region in a first direction; a device isolation layer that fills a trench that defines the first active pattern and the second active pattern; a first channel pattern that includes a plurality of first semiconductor patterns that are spaced apart from each other and vertically stacked on the first active pattern; a second channel pattern that includes a plurality of second semiconductor patterns that are spaced apart from each other and vertically stacked on the second active pattern; a first gate electrode on the first channel pattern; a second gate electrode on the second channel pattern; a first interlayer dielectric layer on the first gate electrode and the second gate electrode; and a plurality of gate contacts that penetrate the first interlayer dielectric layer and contact the first gate electrode and the second gate electrode. The first gate electrode includes: a plurality of first metal patterns on the plurality of first semiconductor patterns on the first active region; and a gap-fill pattern between the plurality of first metal patterns on the first active region. A maximum width in the first direction of the gap-fill pattern is less than a maximum width in the first direction of the plurality of first metal patterns.

### BRIEF DESCRIPTION OF DRAWINGS

The above and other aspects, features and advantages of embodiments will be more apparent from the following description, taken in conjunction with the accompanying drawings.

FIGS. 1 to 3 illustrate conceptual diagrams showing logic cells of a semiconductor device according to some embodiments.

FIG. 4 illustrates a plan view showing a semiconductor device according to some embodiments.

FIGS. 5A, 5B, 5C, and 5D illustrate cross-sectional views respectively taken along lines A-A′, B-B′, C-C′, and D-D′ of FIG. 4.

FIG. 6A illustrate an enlarged view showing section P of FIG. 5D.

FIG. 6B illustrate an enlarged view showing a semiconductor device according to some embodiments, which corresponds to FIG. 6A.

FIGS. 7A, 7B, 8A, 8B, 9A, 9B, 9C, 10A, 10B, 10C, 11A, 11B, 11C, 12A, 12B and 12C illustrate cross-sectional views showing a method of fabricating a semiconductor device according to some embodiments.

FIGS. 13 to 20 illustrate enlarged views showing a method of forming a gate electrode according to some embodiments.

### DETAILED DESCRIPTION

Hereinafter, embodiments will be described in detail with reference to the accompanying drawings. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

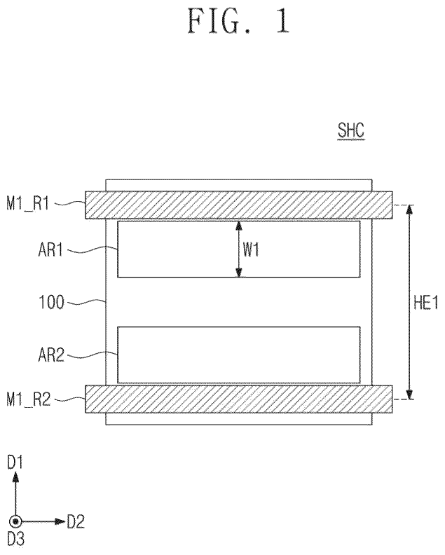

FIGS. 1 to 3 illustrate conceptual diagrams showing logic cells of a semiconductor device according to some embodiments.

Referring to FIG. 1, a single height cell SHC may be provided. For example, a first power line M1_R1 and a second power line M1_R2 may be provided on a substrate 100. The first power line M1_R1 may be a path for providing a source voltage, for example, a ground voltage. The second power line M1_R2 may be a path for providing a drain voltage, for example, a power voltage.

The single height cell SHC may be defined between the first power line M1_R1 and the second power line M1_R2. The single height cell SHC may include one first active region AR1 and one second active region AR2. One of the first and second active regions AR1 and AR2 may be a p-type metal-oxide-semiconductor field-effect transistor (PMOSFET) region, and the other of the first and second active regions AR1 and AR2 may be an n-type metal-oxide-semiconductor field-effect transistor (NMOSFET) region. For example, the single height cell SHC may have a complementary metal oxide semiconductor (CMOS) structure provided between the first power line M1_R1 and the second power line M1_R2.

Each of the first and second active regions AR1 and AR2 may have a first width W1 in a first direction D1. A first height HE1 may be defined to refer to a length in the first direction D1 of the single height cell SHC. The first height HE1 may be substantially the same as a distance (e.g., pitch) between the first power line M1_R1 and the second power line M1_R2.

The single height cell SHC may constitute one logic cell. In this disclosure, the logic cell may indicate a logic device (e.g., AND, OR, XOR, XNOR, and inverter) that performs a specific function. For example, the logic cell may include transistors for constituting a logic device, and may also include wiring lines that connect the transistors to each other.

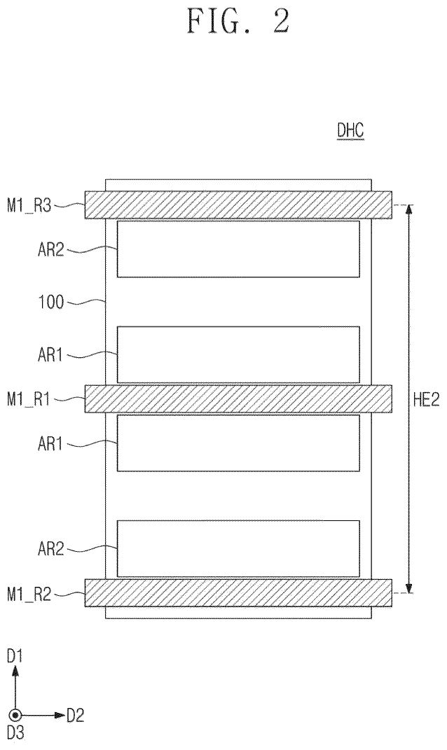

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a source voltage (VSS).

The double height cell DHC may be defined between the second power line M1_R2 and the third power line M1_R3. The double height cell DHC may include two first active regions AR1 and two second active regions AR2.

One of the two second active regions AR2 may be adjacent to the second power line M1_R2. The other of the two second active regions AR2 may be adjacent to the third power line M1_R3. The two first active regions AR1 may be adjacent to the first power line M1_R1. When viewed in plan, the first power line M1_R1 may be disposed between the two first active regions AR1.

A second height HE2 may be defined to refer to a length in the first direction D1 of the double height cell DHC. The second height HE2 may be about twice the first height HE1 of FIG. 1. The two first active regions AR1 of the double height cell DHC may be collectively connected to act as one active region.

The double height cell DHC shown in FIG. 2 may be defined as a multi-height cell. Another multi-height cell may include a triple height cell whose cell height is about three times that of the single height cell SHC.

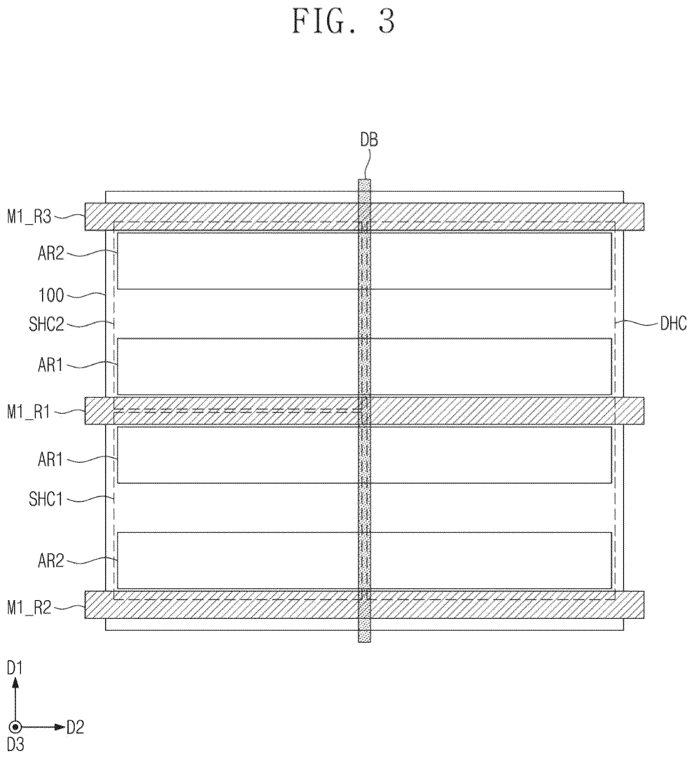

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2.

A separation structure DB may be provided between the first single height cell SHC1 and the double height cell DHC, and between the second single height cell SHC2 and the double height cell DHC. The separation structure DB may electrically separate an active region of the double height cell DHC from an active region of each of the first and second single height cells SHC1 and SHC2.

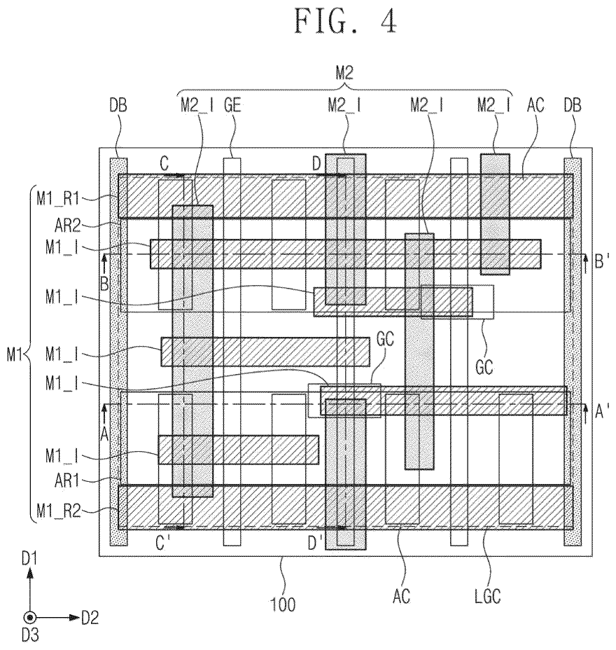

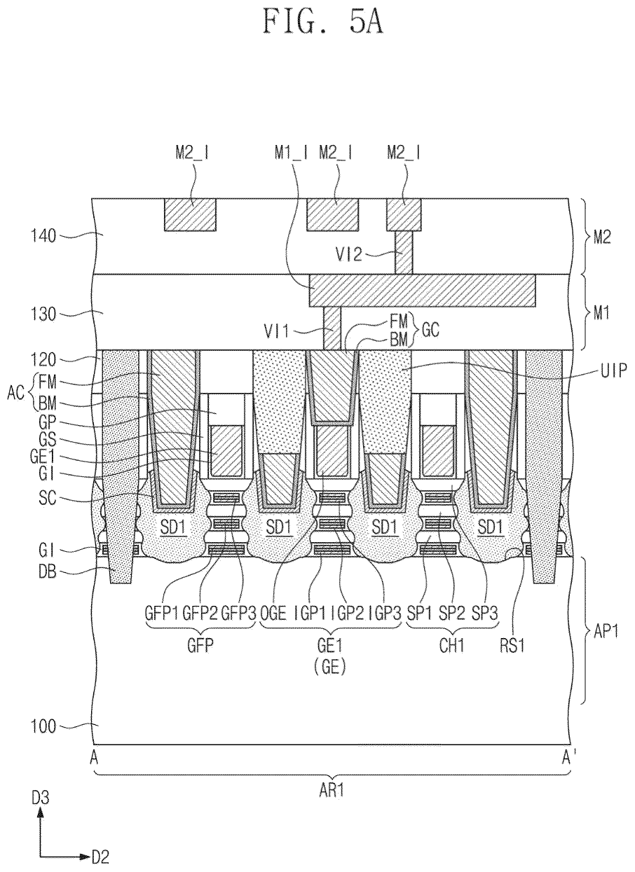

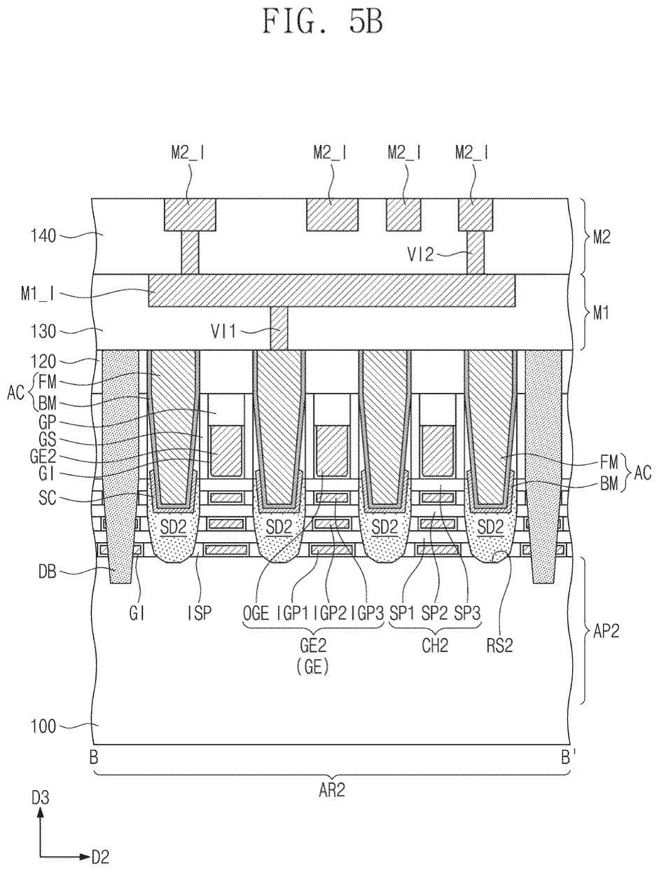

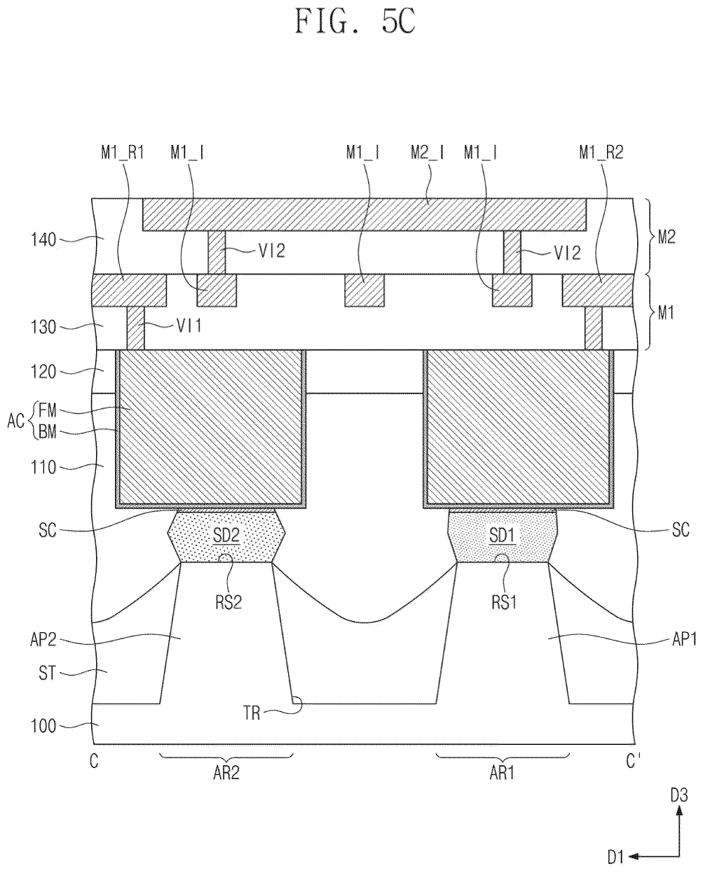

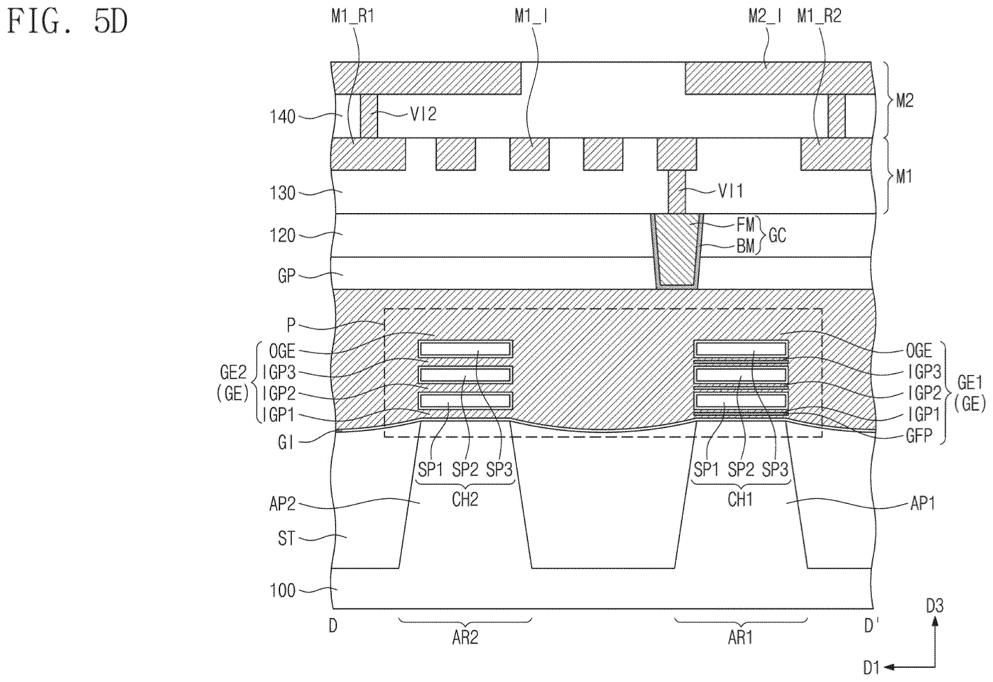

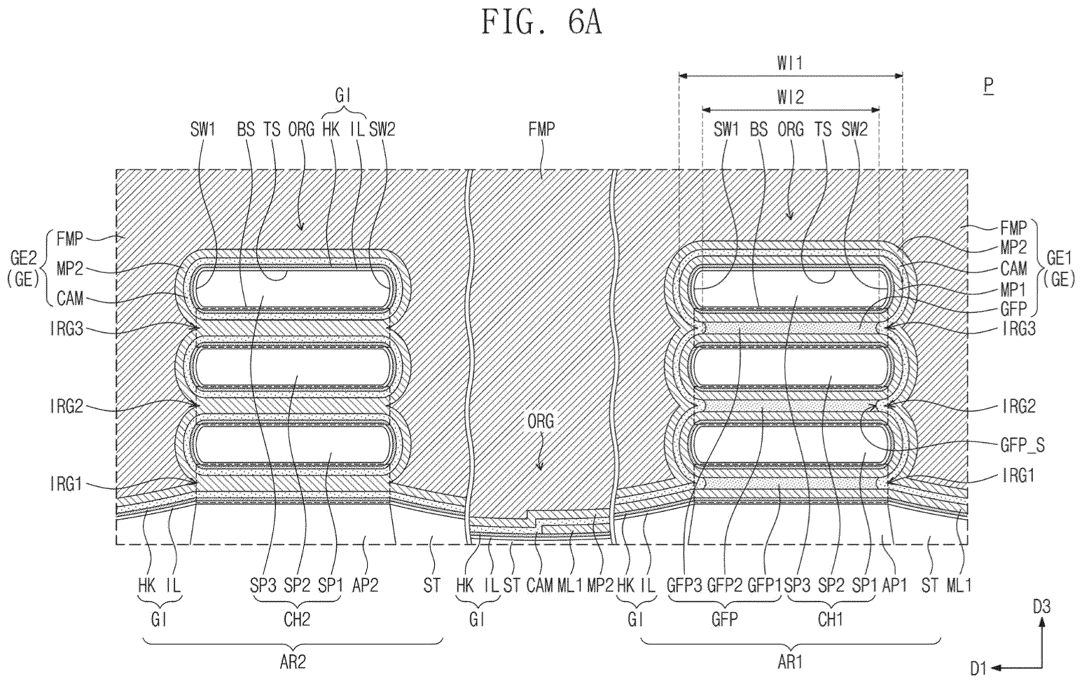

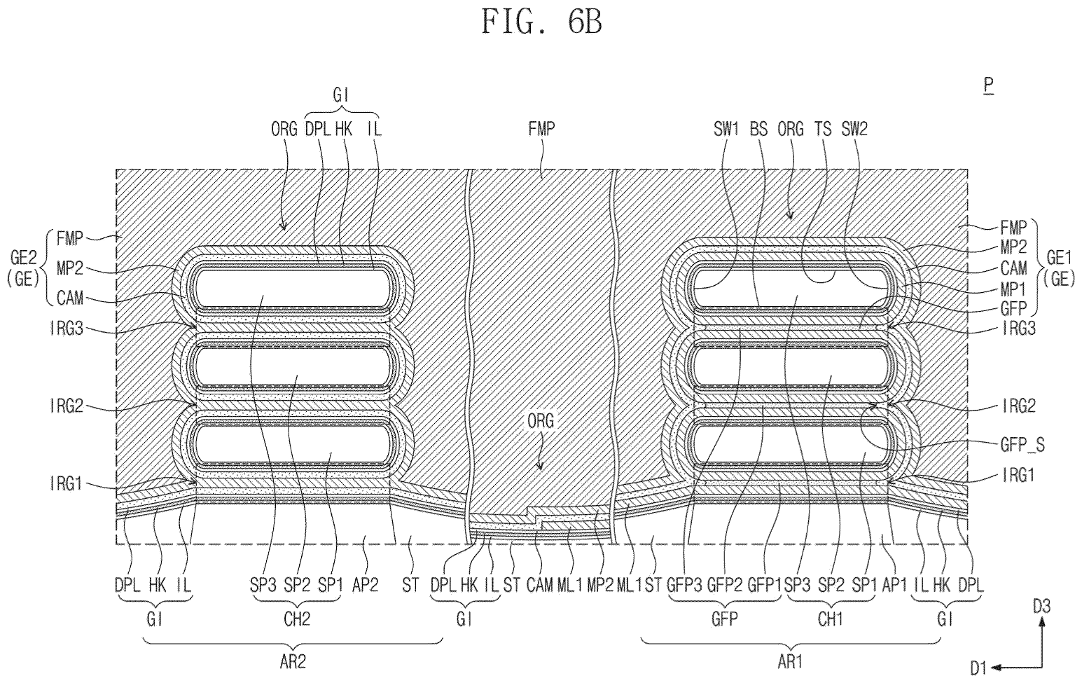

FIG. 4 illustrates a plan view showing a semiconductor device according to some embodiments. FIGS. 5A, 5B, 5C, and 5D illustrate cross-sectional views respectively taken along lines A-A′, B-B′, C-C′, and D-D′ of FIG. 4. FIG. 6A illustrate an enlarged view showing section P of FIG. 5D.

Referring to FIGS. 4 and 5A to 5D, a logic cell LGC may be provided on a substrate 100. The logic cell LGC may be provided thereon with logic transistors included in a logic circuit. The substrate 100 may be a compound semiconductor substrate or a semiconductor substrate including silicon, germanium, or silicon-germanium. For example, the substrate 100 may be a silicon substrate.

The substrate 100 may include a first active region AR1 and a second active region AR2. The first active region AR1 and the second active region AR2 may be spaced apart from each other in a first direction D1. For example, the first active region AR1 may be a PMOSFET region, and the second active region AR2 may be an NMOSFET region.

A first active pattern AP1 and a second active pattern AP2 may be defined by a trench TR formed on an upper portion of the substrate 100. The first and second active patterns AP1 and AP2 may be respectively provided on the first and second active regions AR1 and AR2. The first and second active patterns AP1 and AP2 may extend in a second direction D2. The first and second active patterns AP1 and AP2 may be vertically protruding portions of the substrate 100.

The trench TR may be filled with a device isolation layer ST. The device isolation layer ST may include a silicon oxide layer. The device isolation layer ST may not cover any of first and second channel patterns CH1 and CH2 which will be discussed below.

A first channel pattern CH1 and a second channel pattern CH2 may be respectively provided on the first active pattern AP1 and the second active pattern AP2. Each of the first and second channel patterns CH1 and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (e.g., a third direction D3). The third semiconductor pattern SP3 may denote an uppermost one of the first to third semiconductor patterns SP1, SP2, and SP3.

Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon, for example, monocrystalline silicon. In an embodiment, the first, second, and third semiconductor patterns SP1, SP2, and SP3 may be stacked nano-sheets.

A plurality of first source/drain patterns SD1 may be provided on the first active pattern AP1. A plurality of first recesses RS1 may be formed on an upper portion of the first active pattern AP1. The first source/drain patterns SD1 may be correspondingly provided in the first recesses RS1. The first source/drain patterns SD1 may be impurity regions having a first conductivity type (e.g., p-type). The first channel pattern CH1 may be interposed between a pair of first source/drain patterns SD1. For example, the pair of first source/drain patterns SD1 may be connected through the stacked first, second, and third semiconductor patterns SP1, SP2, and SP3.

A plurality of second source/drain patterns SD2 may be provided on the second active pattern AP2. A plurality of second recesses RS2 may be formed on an upper portion of the second active pattern AP2. The second source/drain patterns SD2 may be correspondingly provided in the second recesses RS2. The second source/drain patterns SD2 may be impurity regions having a second conductivity type (e.g., n-type). The second channel pattern CH2 may be interposed between a pair of second source/drain patterns SD2. For example, the pair of second source/drain patterns SD2 may be connected through the stacked first, second, and third semiconductor patterns SP1, SP2, and SP3.

The first and second source/drain patterns SD1 and SD2 may be epitaxial patterns formed by a selective epitaxial growth (SEG) process. For example, each of the first and second source/drain patterns SD1 and SD2 may have a top surface higher than that of the third semiconductor pattern SP3. For another example, at least one of the first and second source/drain patterns SD1 and SD2 may have a top surface at substantially the same level as that of a top surface of the third semiconductor pattern SP3.

In an embodiment, the first source/drain patterns SD1 may include a semiconductor element (e.g., SiGe) whose lattice constant is greater than that of a semiconductor element of the substrate 100. Therefore, a pair of first source/drain patterns SD1 may provide a compressive stress to the first channel pattern CH1 therebetween. The second source/drain patterns SD2 may include the same semiconductor element (e.g., Si) as that of the substrate 100.

In an embodiment, the first source/drain pattern SD1 may have an uneven embossing shape on a sidewall thereof. For example, the sidewall of the first source/drain pattern SD1 may have a wavy profile. The sidewall of the first source/drain pattern SD1 may protrude toward first, second, and third inner portions IGP1, IGP2, and IGP3 of a gate electrode GE which will be discussed below.

The logic cell LGC may be provided thereon with gate electrodes GE that extend in the first direction D1 and run across the first and second channel patterns CH1 and CH2. Each of the gate electrodes GE may vertically overlap the first and second channel patterns CH1 and CH2. The gate electrodes GE may be spaced apart from each other in the second direction D2.

Referring back to FIG. 5D, the gate electrode GE may be provided on a top surface, a bottom surface, and opposite sidewalls of each of the first, second, and third semiconductor patterns SP1, SP2, and SP3. In this regard, a transistor may be a three-dimensional field effect transistor (FET) (e.g., multi-bridge channel FET (MBCFET)) in which the gate electrode GE three-dimensionally surrounds the first and second channel patterns CH1 and CH2.

The gate electrodes GE may each include a first gate electrode GE1 on the first channel pattern CH1 and a second gate electrode GE2 on the second channel pattern CH2.

The first gate electrode GE1 may include a first inner portion IGP1 between the first active pattern AP1 and the first semiconductor pattern SP1, a second inner portion IGP2 between the first semiconductor pattern SP1 and the second semiconductor pattern SP2, and a third inner portion IGP3 between the second semiconductor pattern SP2 and the third semiconductor pattern SP3. Gap-fill patterns GFP may be correspondingly provided in the first, second, and third inner portions IGP1, IGP2, and IGP3. For example, the gap-fill patterns GFP may be correspondingly provided between the first active pattern AP1 and the first semiconductor pattern SP1, between the first semiconductor pattern SP1 and the second semiconductor pattern SP2, and between the second semiconductor pattern SP2 and the third semiconductor pattern SP3. The first gate electrode GE1 may further include an outer gate electrode OGE on the first, second, and third inner portions IGP1, IGP2, and IGP3.

The second gate electrode GE2 may include a first inner portion IGP1 between the second active pattern AP2 and the first semiconductor pattern SP1, a second inner portion IGP2 between the first semiconductor pattern SP1 and the second semiconductor pattern SP2, and a third inner portion IGP3 between the second semiconductor pattern SP2 and the third semiconductor pattern SP3. The second gate electrode GE2 may further include an outer gate electrode OGE on the first, second, and third inner portions IGP1, IGP2, and IGP3.

The first gate electrode GE1 and the second gate electrode GE2 may be connected to each other, and may extend along the first direction D1. The first gate electrode GE1 and the second gate electrode GE2 may share the outer gate electrode OGE.

Referring back to FIGS. 4 and 5A to 5D, a pair of gate spacers GS may be disposed on opposite sidewalls of the outer gate electrode OGE. The gate spacers GS may extend in the first direction D1 along the gate electrode GE. The gate spacers GS may have top surfaces higher than that of the outer gate electrode OGE. The top surfaces of the gate spacers GS may be coplanar with that of a first interlayer dielectric layer 110 which will be discussed below. The gate spacers GS may include at least one selected from SiCN, SiCON, and SiN. Alternatively, the gate spacers GS may each include a multiple layer formed of at least two selected from SiCN, SiCON, and SiN.

A gate capping pattern GP may be provided on the gate electrode GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include at least one selected from SiON, SiCN, SiCON, and SiN.

Gate dielectric layers GI may be correspondingly interposed between the first gate electrode GE1 and the first channel pattern CH1 and between the second gate electrode GE2 and the second channel pattern CH2. The gate dielectric layer GI may cover a top surface, a bottom surface, and opposite sidewalls of each of the first, second, and third semiconductor patterns SP1, SP2, and SP3. The gate dielectric layer GI may cover a top surface of the device isolation layer ST that underlies the gate electrode GE (see FIG. 5D).

In an embodiment, the gate dielectric layer GI may include one or more of a silicon oxide layer, a silicon oxynitride layer, and a high-k dielectric layer. For example, as shown in FIG. 6A, the gate dielectric layer GI may have a structure in which an interface layer IL and a high-k dielectric layer HK are stacked. The interface layer IL may include a silicon oxide layer or a silicon oxynitride layer. The high-k dielectric layer HK may include a high-k dielectric material whose dielectric constant is greater than that of a silicon oxide layer. For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Alternatively, a semiconductor device according to embodiments may include a negative capacitance (NC) FET that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing of less than about 60 mV/decade at room temperature.

The ferroelectric material layer may have ferroelectric properties. The ferroelectric material layer may include, for example, at least one selected from hafnium oxide, hafnium zirconium oxide, barium strontium titanium oxide, and lead zirconium titanium oxide. For example, the hafnium zirconium oxide may be a material in which hafnium oxide is doped with zirconium (Zr). For another example, the hafnium zirconium oxide may be a compound of hafnium (Hf), zirconium (Zr), and oxygen (O).

The ferroelectric material layer may further include impurities doped therein. For example, the impurities may include at least one selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of impurities included in the ferroelectric material layer may be changed depending on what ferroelectric material is included in the ferroelectric material layer.

When the ferroelectric material layer includes hafnium oxide, the ferroelectric material layer may include at least one of impurities such as gadolinium (Gd), silicon (Si), zirconium (Zr), aluminum (Al), and yttrium (Y).

The paraelectric material layer may have paraelectric properties. The paraelectric material layer may include, for example, at least one selected from silicon oxide and high-k metal oxide. The metal oxide included in the paraelectric material layer may include, for example, at least one selected from hafnium oxide, zirconium oxide, and aluminum oxide, but embodiments are not limited thereto.

The ferroelectric material layer and the paraelectric material layer may include the same material. The ferroelectric material layer may have ferroelectric properties, but the paraelectric material layer may not have ferroelectric properties. For example, when the ferroelectric material layer and the paraelectric material layer include hafnium oxide, a crystal structure of the hafnium oxide included in the ferroelectric material layer may be different from that of the hafnium oxide included in the paraelectric material layer.

The ferroelectric material layer may have a thickness having ferroelectric properties. The thickness of the ferroelectric material layer may range, for example, from about 0.5 nm to about 10 nm, but embodiments are not limited thereto. Because ferroelectric materials have their own critical thickness that exhibits ferroelectric properties, the thickness of the ferroelectric material layer may depend on ferroelectric material.

For example, the gate dielectric layer GI may include a ferroelectric material layer. For another example, the gate dielectric layer GI may include a plurality of ferroelectric material layers that are spaced apart from each other. The gate dielectric layer GI may have a stack structure in which a plurality of ferroelectric material layers are alternately stacked with a plurality of paraelectric material layers.

On the second active region AR2, inner spacers ISP may be correspondingly interposed between the second source/drain pattern SD2 and the first, second, and third inner portions IGP1, IGP2, and IGP3 of the second gate electrode GE2. Each of the first, second, and third inner portions IGP1, IGP2, and IGP3 of the second gate electrode GE2 may be spaced apart from the second source/drain pattern SD2 across the inner spacer ISP. The inner spacer ISP may prevent a leakage current from the second gate electrode GE2.

A first interlayer dielectric layer 110 may be provided on the substrate 100. The first interlayer dielectric layer 110 may cover the gate spacers GS and the first and second source/drain patterns SD1 and SD2. The first interlayer dielectric layer 110 may have a top surface substantially coplanar with that of the gate capping pattern GP and that of the gate spacer GS. A second interlayer dielectric layer 120 that covers the gate capping pattern GP may be provided on the first interlayer dielectric layer 110. For example, the first and second interlayer dielectric layers 110 and 120 may include a silicon oxide layer.

The logic cell LGC may be provided on its opposite sides with a pair of separation structures DB that are opposite to each other in the second direction D2. The separation structure DB may extend in the first direction D1 parallel to the gate electrodes GE.

The separation structure DB may penetrate the first and second interlayer dielectric layers 110 and 120 to extend into the active pattern AP1 or AP2. The separation structure DB may penetrate the channel pattern CH1 or CH2. The separation structure DB may separate the active region AR1 or AR2 of the logic cell LGC from an active region of another logic cell.

Active contacts AC may be provided to penetrate the first and second interlayer dielectric layers 110 and 120 to come into electrical connection with the first and second source/drain patterns SD1 and SD2. A pair of active contacts AC may be provided on opposite sides of the gate electrode GE. When viewed in plan, the active contact AC may have a bar shape that extends in the first direction D1.

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. The active contact AC may cover a portion of the top surface of the gate capping pattern GP.

A metal-semiconductor compound layer SC, such as a silicide layer, may be interposed between the active contact AC and the source/drain pattern SD1 or SD2. The active contact AC may be electrically connected through the metal-semiconductor compound layer SC to the source/drain pattern SD1 or SD2. For example, the metal-semiconductor compound layer SC may include at least one selected from titanium silicide, tantalum silicide, tungsten silicide, nickel silicide, and cobalt silicide.

A gate contact GC may be provided to penetrate the second interlayer dielectric layer 120 and the gate capping pattern GP to come into electrical connection with the gate electrode GE. For example, referring to FIG. 5A, each of the active contacts AC adjacent to the gate contact GC may have an upper portion, and the upper portion of the active contact AC may be filled with an upper dielectric pattern UIP. For example, the gate contact GC may be provided between the upper portions UIP of the adjacent gate contacts. Therefore, a process failure that is due to an electrical short caused by contact between the gate contact GC and its adjacent active contact AC.

Each of the active contact AC and the gate contact GC may include a conductive pattern FM and a barrier pattern BM that surrounds the conductive pattern FM. For example, the conductive pattern FM may include at least one metal selected from aluminum, copper, tungsten, molybdenum, and cobalt. The barrier pattern BM may cover sidewalls and a bottom surface of the conductive pattern FM. The barrier pattern BM may include a metal layer and a metal nitride layer. The metal layer may include at least one selected from titanium, tantalum, tungsten, nickel, cobalt, and platinum. The metal nitride layer may include at least one selected from titanium nitride (TiN), tantalum nitride (TaN), tungsten nitride (WN), nickel nitride (NiN), cobalt nitride (CON), and platinum nitride (PtN).

A first metal line M1 may be provided in the third interlayer dielectric layer 130. For example, the first metal line M1 may include a first power line M1_R1, a second power line M1_R2, and first wiring lines M1_I. The lines M1_R1, M1_R2, and M1_I of the first metal line M1 may extend in parallel in the second direction D2.

The first and second power lines M1_R1 and M1_R2 may be correspondingly provided on boundaries of the logic cell LGC. Each of the first and second power lines M1_R1 and M1_R2 may extend in the second direction D2 along the boundary.

The first wiring lines M1_I of the first metal line M1 may be disposed between the first and second power lines M1_R1 and M1_R2. The first wiring lines M1_I of the first metal line M1 may be arranged along the first direction D1. Each of the first wiring lines M1_I may have a line-width less than that of each of the first and second power lines M1_R1 and M1_R2.

The first metal line M1 may further include first vias VI1. The first vias VI1 may be correspondingly provided below the lines M1_R1, M1_R2, and M1_I of the first metal line M1. The active contact AC and a line of the first metal line M1 may be electrically connected to each other through the first via VI1. The gate contact GC and a line of the first metal line M1 may be electrically connected to each other through the first via VI1.

A certain line and its underlying first via VI1 of the first metal line M1 may be formed by individual processes. For example, the certain line and its underlying first via VI1 of the first metal line M1 may each be formed by a single damascene process.

A second metal line M2 may be provided in a fourth interlayer dielectric layer 140. The second metal line M2 may include a plurality of second wiring lines M2_I. Each of the second wiring lines M2_I of the second metal line M2 may have a linear or bar shape that extends in the first direction D1. For example, the second wiring lines M2_I may extend in parallel in the first direction D1.

The second metal line M2 may further include second vias VI2 that are correspondingly provided below the second wiring lines M2_I. A line of the first metal line M1 may be electrically connected through the second via VI2 to a line of the second metal line M2. For example, a certain line and its underlying second via VI2 of the second metal line M2 may be simultaneously formed by a dual damascene process.

A line of the first metal line M1 and a line of the second metal line M2 may include the same or different conductive materials. For example, a line of the first metal line M1 and a line of the second metal line M2 may include at least one metallic material selected from aluminum, copper, tungsten, molybdenum, ruthenium, and cobalt.

The gate electrode GE will be further discussed in detail with reference to FIGS. 5D and 6A. The gate electrode GE may include a first gate electrode GE1 on the first active region AR1 and a second gate electrode GE2 on the second active region AR2. The first gate electrode GE1 may indicate the gate electrode GE on the first active region AR1, the second gate electrode GE2 may indicate the gate electrode GE on the second active region AR2, and the first gate electrode GE1 and the second gate electrode GE2 may be connected to each other along the first direction D1.

The gate electrode GE may include first metal patterns MP1, a first metal layer ML1, cap-fill patterns GFP, a second metal pattern MP2, a capping pattern CAM, and a filling metal pattern FMP. The first gate electrode GE1 on the first active region AR1 may include the first metal patterns MP1, the first metal layer ML1, the gap-fill patterns GFP, the second metal pattern MP2, the capping pattern CAM, and the filling metal pattern FMP. The second gate electrode GE2 on the second active region AR2 may include the second metal pattern MP2, the capping pattern CAM, and the filling metal pattern FMP. For example, each of the first metal patterns MP1 and the gap-fill patterns GFP may be offset from the second active region AR2, and in this regard neither the first metal patterns MP1 nor the gap-fill patterns GFP may be disposed on the second active region AR2.

The gate dielectric layer GI may cover a surface of each of the first, second, and third semiconductor patterns SP1, SP2, and SP3. The gate dielectric layer GI may include the interface layer IL and the high-k dielectric layer HK on the interface layer IL. The interface layer IL may directly cover the surface of each of the first, second, and third semiconductor patterns SP1, SP2, and SP3. The high-k dielectric layer HK may be spaced apart across the interface layer IL from the first, second, and third semiconductor patterns SP1, SP2, and SP3. A thickness of the high-k dielectric layer HK may be greater than that of the interface layer IL.

On the first active region AR1, a first inner region IRG1 may be defined between the first active pattern AP1 and the first semiconductor pattern SP1, a second inner region IRG2 may be defined between the first semiconductor pattern SP1 and the second semiconductor pattern SP2, and a third inner region IRG3 may be defined between the second semiconductor pattern SP2 and the third semiconductor pattern SP3. A region other than the first, second, and third inner regions IRG1, IRG2, and IRG3 may be defined as an outer region ORG.

Likewise, on the second active region AR2, a first inner region IRG1 may be defined between the second active pattern AP2 and the first semiconductor pattern SP1, a second inner region IRG2 may be defined between the first semiconductor pattern SP1 and the second semiconductor pattern SP2, and a third inner region IRG3 may be defined between the second semiconductor pattern SP2 and the third semiconductor pattern SP3. A region other than the first, second, and third inner regions IRG1, IRG2, and IRG3 may be defined as an outer region ORG.

The first metal patterns MP1 may be disposed on a top surface TS, a bottom surface BS, and opposite sidewalls SW1 and SW2 of each of the first, second, and third semiconductor patterns SP1, SP2, and SP3. On the first active region AR1, the first metal patterns MP1 may be in contact with the gate dielectric layer GI. The first metal patterns MP1 may be spaced apart from each other along a vertical direction (or a third direction D3). The first metal patterns MP1 may fill portions of the first, second, and third inner regions IRG1, IRG2, and IRG3 on the first active region AR1.

The first metal patterns MP1 may include a first work-function metal. The first work-function metal may be a p-type work-function metal whose work function is relatively high. For example, the first metal pattern MP1 may include at least one selected from metal oxynitride, metal oxycarbide, and metal oxynitride carbide. The metal may be selected from one or more of Ti, Ta, Nb, Al, W, and Mo. The first metal pattern MP1 may be a single layer or a multiple layer including at least two layers.

The first metal layer ML1 may be disposed on the first active pattern AP1. The first metal layer ML1 may include metal substantially the same as or similar to that of the first metal patterns MP1. For example, the first metal layer ML1 may include the first work-function metal. The first metal layer ML1 may extend to a section between the first and second active regions AR1 and AR2. The first metal layer ML1 may be in contact with the gate dielectric layer GI on the first active pattern AP1.

On the first active region AR1, the gap-fill patterns GFP may be provided between the first metal patterns MP1, and between a lowermost first metal pattern MP1 and the first metal layer ML1. The gap-fill patterns GFP may include first, second, and third gap-fill patterns GFP1, GFP2, and GFP3. The first, second, and third gap-fill patterns GFP1, GFP2, and GFP3 may be respectively provided in the first, second, and third inner regions IRG1, IRG2, and IRG3. For example, the first gap-fill pattern GFP1 may be provided between the first active pattern AP1 and the first semiconductor pattern SP1, the second gap-fill pattern GFP2 may be provided between the first semiconductor pattern SP1 and the second semiconductor pattern SP2, and the third gap-fill pattern GFP3 may be provided between the second semiconductor pattern SP2 and the third semiconductor pattern SP3. The first gap-fill pattern GFP1 may be in contact with the first metal layer ML1 and the lowermost first metal pattern MP1, and the second and third gap-fill patterns GFP2 and GFP3 may be correspondingly in contact in a vertical direction (e.g., the third direction D3) with the first metal patterns MP1. The gap-fill patterns GFP may have sidewalls GFP_S that are not in contact with but spaced apart from the first metal patterns MP1 and the first metal layer ML1.

The gap-fill patterns GFP may have an etch selectivity with respect to the first metal patterns MP1 and the first metal layer ML1. The gap-fill patterns GFP may include at least one selected from metal oxynitride, metal oxycarbide, and metal oxynitride carbide, and may be one of titanium nitride (TiN), molybdenum nitride (MoN), tungsten nitride (WN), aluminum oxide (AlO), and aluminum nitride (AlN).

The gap-fill patterns GFP may have maximum widths WI2 in the first direction D1 less than maximum widths WI1 in the first direction D1 of the first metal patterns MP1. For example, opposite sidewalls of each of the first metal patterns MP1 may horizontally protrude more than the opposite sidewalls GFP_S of each of the gap-fill patterns GFP. The opposite sidewalls GFP_S of the gap-fill pattern GFP may have recessed shape, for example, rounded shapes. The opposite sidewalls GFP_S of the gap-fill patterns GFP may not in contact with the first metal patterns MP1. For example, the maximum width WI2 in the first direction D1 of the gap-fill pattern GFP may denote a maximum distance in the first direction D1 between the opposite sidewalls GFP_S of the gap-fill pattern GFP. The maximum width WI1 in the first direction D1 of the first metal pattern MP1 may denote a maximum distance in the first direction D1 between the opposite sidewalls of the first metal pattern MP1.

On the first active region AR1, the second metal pattern MP2 may be disposed on the first metal patterns MP1. On the first active region AR1, the second metal pattern MP2 may cover the sidewalls of the first metal patterns MP1 and the sidewalls GFP_S of the gap-fill patterns GFP. The second metal pattern MP2 may include a second work-function metal. For example, the second work-function metal may be an n-type work-function metal whose work function is relatively low. The work function of the second work-function metal may be different from and relatively less than that of the first work-function metal.

The second metal pattern MP2 may include metal carbide. The second metal pattern MP2 may include metal carbide doped with (or containing) aluminum. For example, the second metal pattern MP2 may include titanium aluminum carbide (TiAlC), tantalum aluminum carbide (TaAlC), or vanadium aluminum carbide (VAlC). For another example, the second metal pattern MP2 may include aluminum-doped titanium (TiAl) or aluminum-doped titanium nitride (TiAlN).

An aluminum concentration of the second metal pattern MP2 may be different from that of the first metal pattern MP1. For example, the aluminum concentration of the second metal pattern MP2 may be greater than that of the first metal pattern MP1. The work-function of the second metal pattern MP2 may be controlled by adjusting a concentration of dopants (or impurities) such as aluminum. In addition, according to some embodiments, compositions of the first and second metal patterns MP1 and MP2 may be controlled to achieve a target threshold voltage of a transistor.

The gate electrode GE (or the first gate electrode GE1) may further include the capping pattern CAM and the filling metal pattern FMP. On the first active region AR1, the capping pattern CAM may be provided between the first metal pattern MP1 and the second metal pattern MP2. The capping pattern CAM may be a capping layer interposed between the first metal pattern MP1 and the second metal pattern MP2. The capping pattern CAM may include a metal nitride layer. The capping pattern CAM may include nitrogen (N) and at least one metal selected from titanium (Ti), tantalum (Ta), aluminum (Al), tungsten (W), and molybdenum (Mo). For example, the capping pattern CAM may include TiN.

The filling metal pattern FMP may be provided on the second metal pattern MP2. The filling metal pattern FMP may have a resistance less than those of the first and second metal patterns MP1 and MP2. For example, the filling metal pattern FMP may include at least one low-resistance metal, such as aluminum (Al), tungsten (W), titanium (Ti), and tantalum (Ta).

The second metal pattern MP2 may extend onto the second active region AR2. On the second active region AR2, the second metal pattern MP2 may be disposed on the top surface TS, the bottom surface BS, and the opposite sidewalls SW1 and SW2 of each of the first, second, and third semiconductor patterns SP1, SP2, and SP3. On the second active region AR2, the capping pattern CAM may be disposed between the second metal pattern MP2 and the first, second, and third semiconductor patterns SP1, SP2, and SP3. On the second active region AR2, the capping pattern CAM may be in contact with the gate dielectric layer GI. The second metal pattern MP2 may be integrally formed to fill the first, second, and third inner regions IRG1, IRG2, and IRG3 on the second active region AR2.

FIG. 6B illustrate an enlarged view showing a semiconductor device according to some embodiments, which corresponds to FIG. 6A. In the description that follows, a detailed description of technical features repetitive to those discussed above with reference to FIGS. 5D and 6 will be omitted, and a difference thereof will be discussed in detail.

The gate dielectric layer GI may further include a dipole layer DPL on the high-k dielectric layer HK. The dipole layer DPL may include oxide of a dipole element. The dipole element may include lanthanum (La), aluminum (Al), or a combination thereof. For example, the dipole layer DPL may include lanthanum oxide (LaO), aluminum oxide (AlO), or a combination thereof.

As the dipole layer DPL is formed with an extremely small thickness, the dipole layer DPL may not be visible in an electron microscope image. The dipole layer DPL may diffuse the dipole element into the gate dielectric layer GI. Thus, lanthanum (La), aluminum (Al), or a combination thereof may be contained as impurities in the gate dielectric layer GI.

When the gate dielectric layer GI contains lanthanum (La), there may be a reduction in effective work function of the gate electrode GE. When the gate dielectric layer GI contains aluminum (Al), there may be an increase in effective work function of the second gate electrode GE2. In an embodiment, the gate dielectric layer GI may include lanthanum La having a low work-function dipole.

The dipole layer DPL of the gate dielectric layer GI may be selectively formed only on a portion of the first and second active regions AR1 and AR2. For example, the gate dielectric layer GI on the first active region AR1 may not include the dipole layer DPL, but the gate dielectric layer GI on the second active region AR2 may include the dipole layer DPL. Likewise, the gate dielectric layer GI on the first active region AR1 may include the dipole layer DPL, but the gate dielectric layer GI on the second active region AR2 may not include the dipole layer DPL.

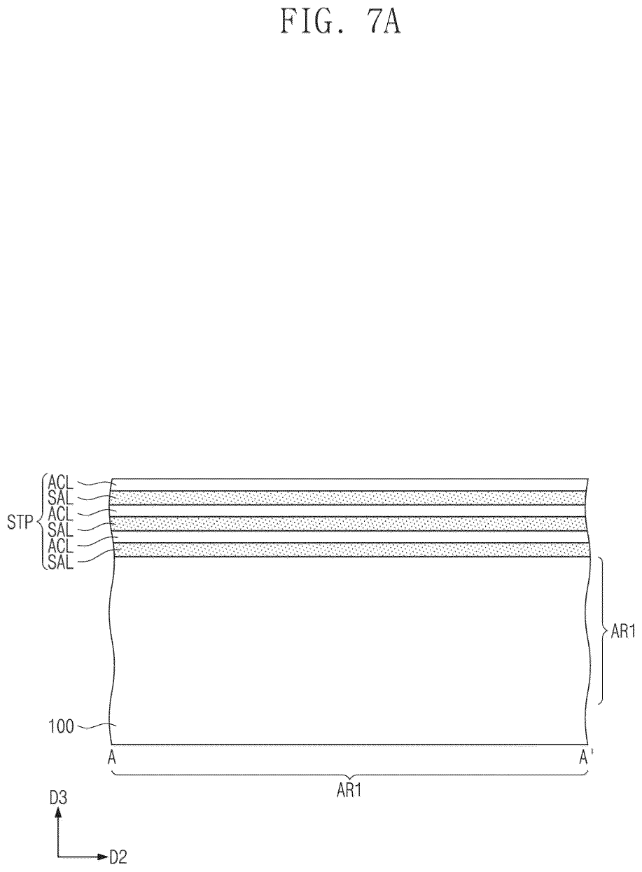

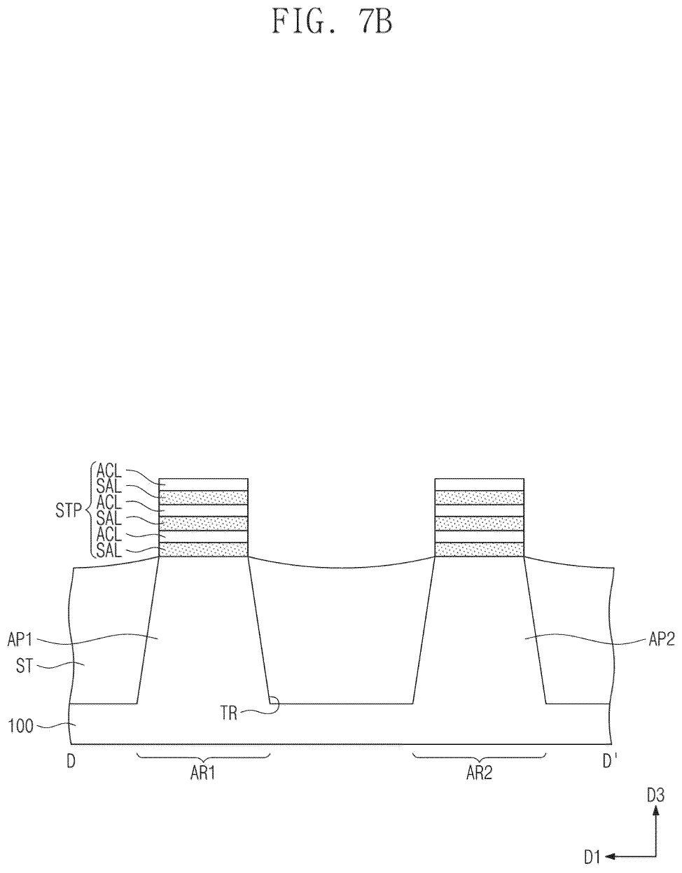

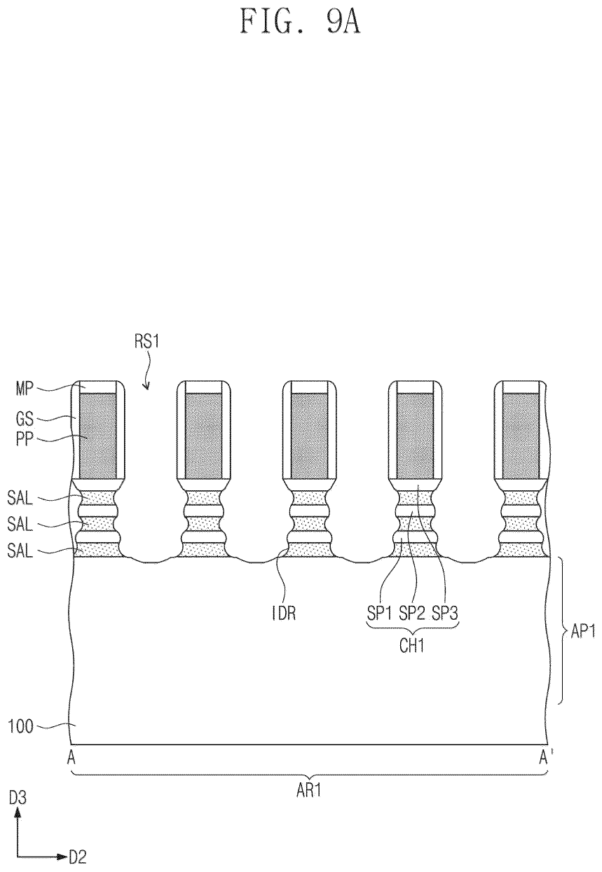

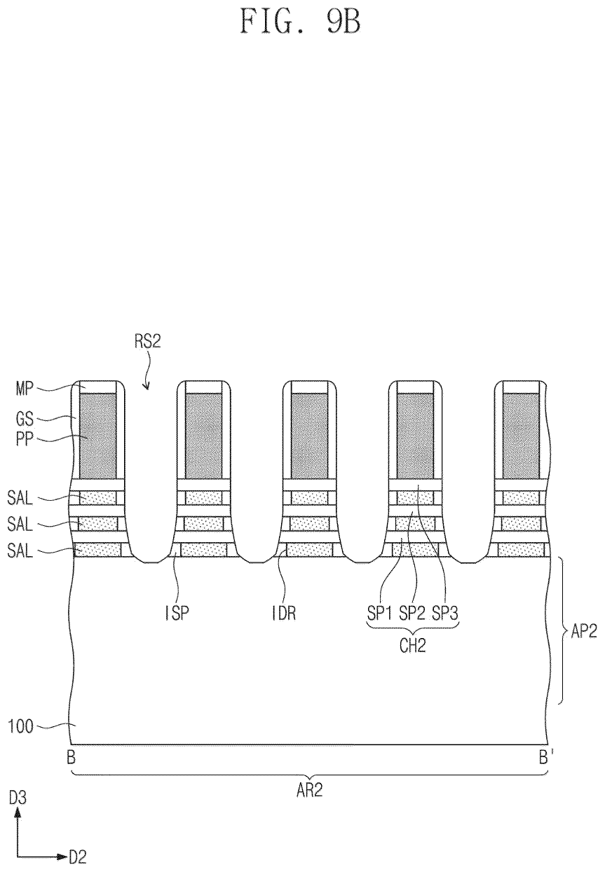

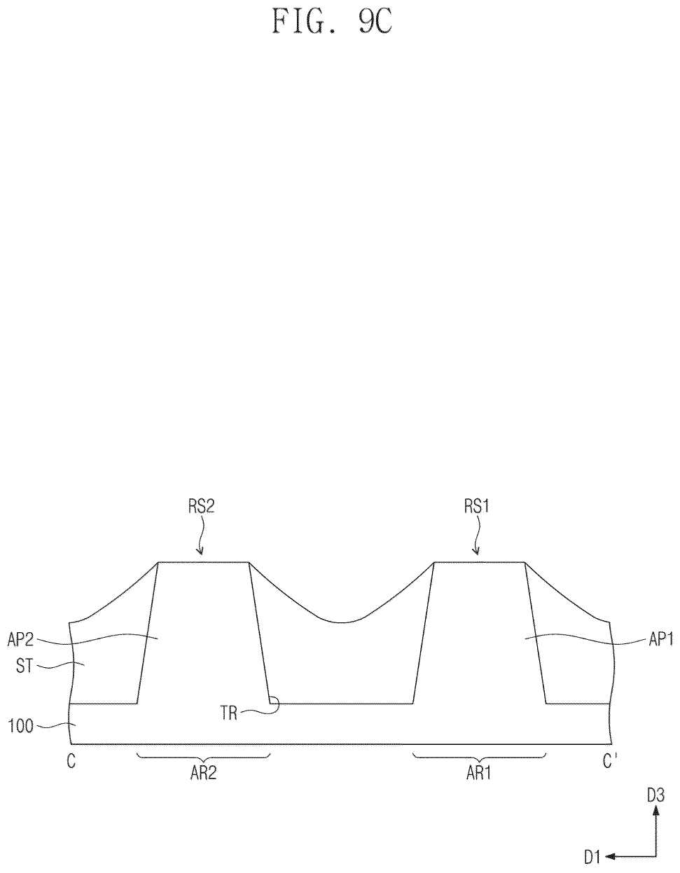

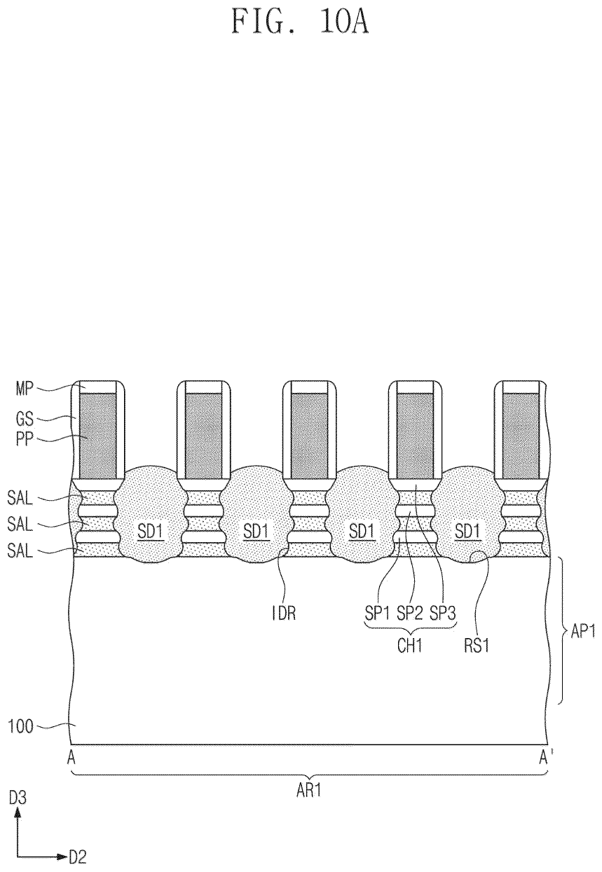

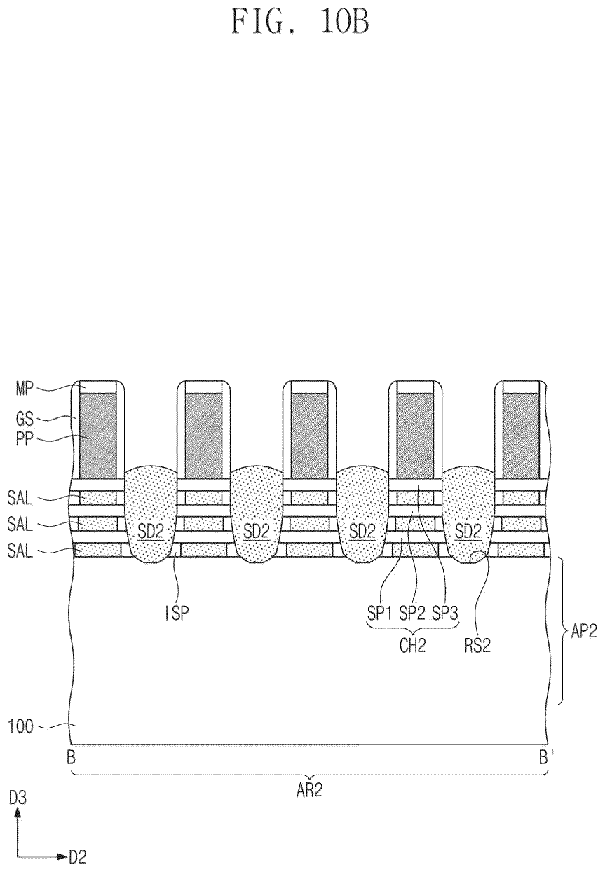

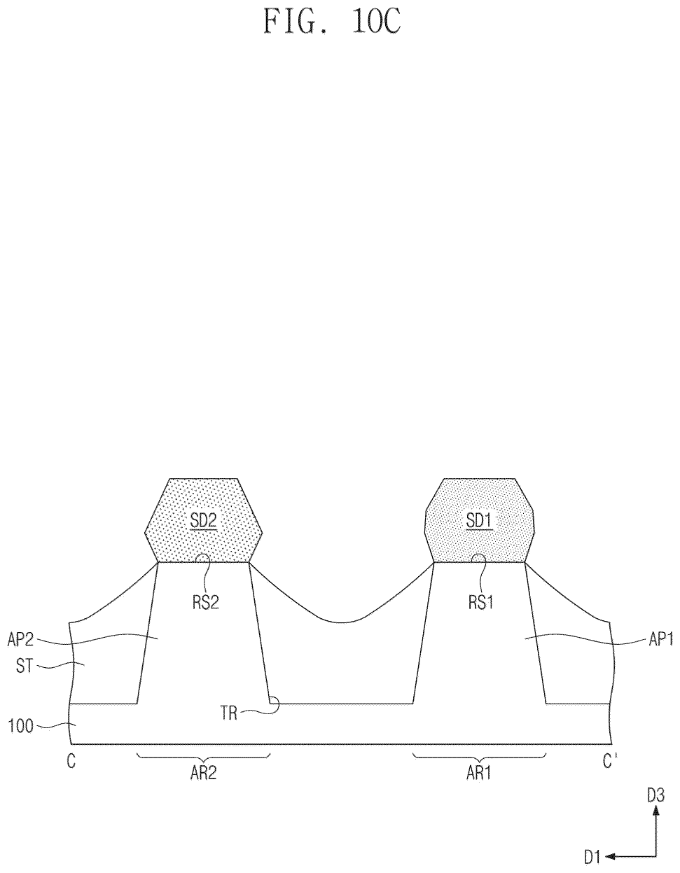

FIGS. 7A to 12C illustrate cross-sectional views showing a method of fabricating a semiconductor device according to some embodiments. In detail, FIGS. 7A, 8A, 9A, 10A, 11A, and 12A illustrate cross-sectional views that correspond to FIG. 5A. FIGS. 9B, 10B, 11B, and 12B illustrate cross-sectional views that correspond to FIG. 5B. FIGS. 9C and 10C illustrate cross-sectional views that correspond to FIG. 5C. FIGS. 7B, 8B, 11C, and 12C illustrate cross-sectional views that correspond to FIG. 5D.

Referring to FIGS. 7A and 7B, a substrate 100 may be provided which includes a first active region AR1 and a second active region AR2. Active layers ACL and sacrificial layers SAL may be alternately formed on the substrate 100. The active layers ACL may include one of silicon (Si), germanium (Ge), and silicon-germanium (SiGe), and the sacrificial layers SAL may include another of silicon (Si), germanium (Ge), and silicon-germanium (SiGe).

The sacrificial layer SAL may include a material having an etch selectivity with respect to the active layer ACL. For example, the active layers ACL may include silicon (Si), and the sacrificial layers SAL may include silicon-germanium (SiGe). Each of the sacrificial layers SAL may have a germanium concentration of about 10 at % to about 30 at %.

Mask patterns may be correspondingly formed on the first and second active regions AR1 and AR2 of the substrate 100. The mask pattern may have a linear or bar shape that extends in a second direction D2.

A patterning process may be performed in which the mask patterns are used as an etching mask to form a trench TR that defines a first active pattern AP1 and a second active pattern AP2. The first active pattern AP1 may be formed on the first active region AR1. The second active pattern AP2 may be formed on the second active region AR2.

A stack pattern STP may be formed on each of the first and second active patterns AP1 and AP2. The stack pattern STP may include the active layers ACL and the sacrificial layers SAL that are alternately stacked. During the patterning process, the stack pattern STP may be formed simultaneously with the first and second active patterns AP1 and AP2.

A device isolation layer ST may be formed to fill the trench TR. For example, a dielectric layer may be formed on a front surface of the substrate 100 to cover the stack patterns STP and the first and second active patterns AP1 and AP2. The dielectric layer may be recessed until the stack patterns STP are exposed, and thus the device isolation layer ST may be formed.

The device isolation layer ST may include a dielectric material, such as a silicon oxide layer. The stack patterns STP may be exposed upwardly from the device isolation layer ST. For example, the stack patterns STP may vertically protrude upwards from the device isolation layer ST.

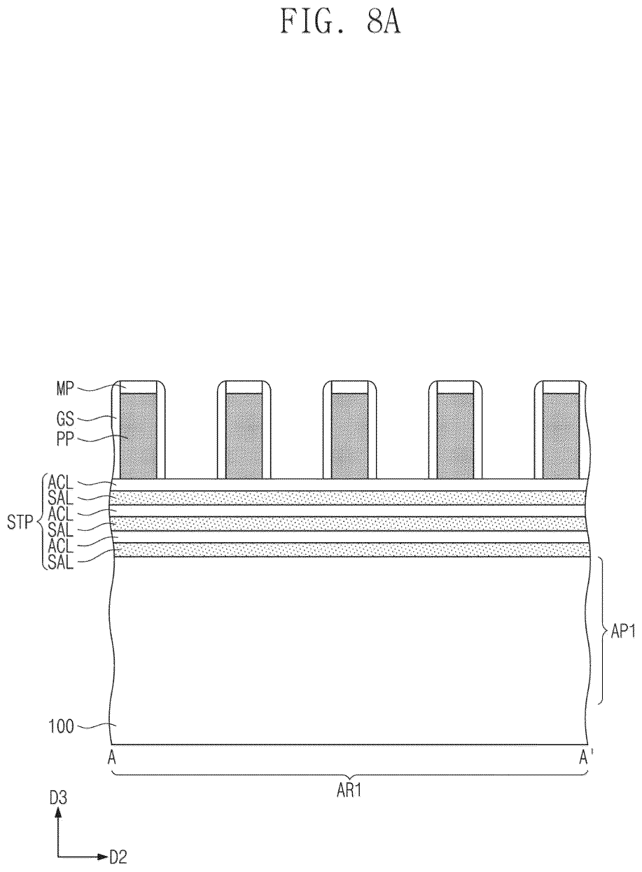

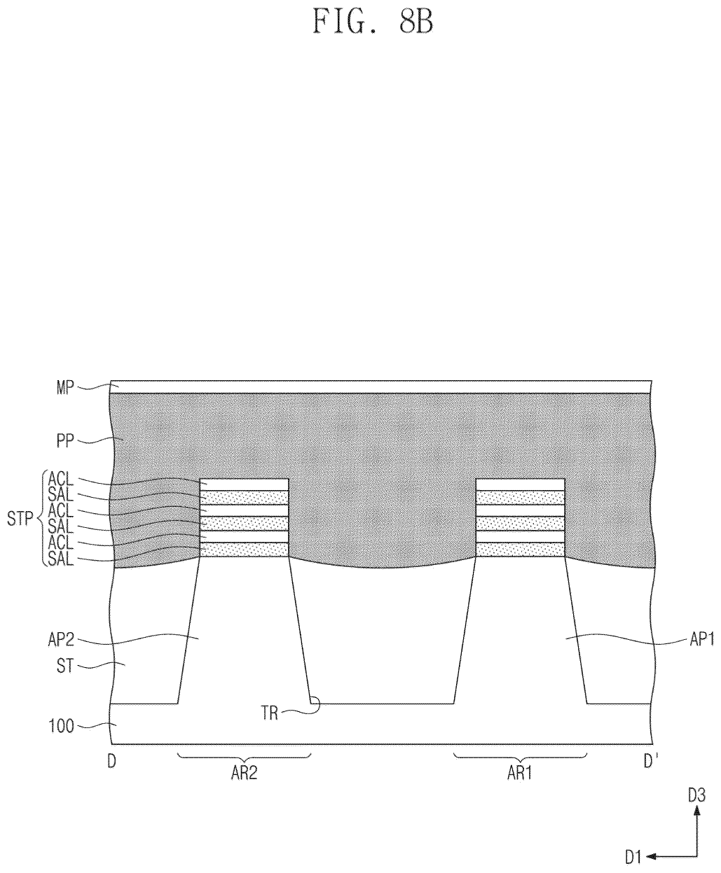

Referring to FIGS. 8A and 8B, sacrificial patterns PP running across the stack patterns STP may be formed on the substrate 100. Each of the sacrificial patterns PP may be formed to have a linear or bar shape that extends in a first direction D1. The sacrificial patterns PP may be spaced apart from each other in the second direction D2.

For example, the formation of the sacrificial patterns PP may include forming a sacrificial layer on the front surface of the substrate 100, forming hardmask patterns MP on the sacrificial layer, and using the hardmask patterns MP as an etching mask to pattern the sacrificial layer. The sacrificial layer may include polysilicon.

A pair of gate spacers GS may be formed on opposite sidewalls of each of the sacrificial patterns PP. The formation of the gate spacers GS may include conformally forming a gate spacer layer on the front surface of the substrate 100 and anisotropically etching the gate spacer layer. In an embodiment, the gate spacer GS may be a multiple layer including at least two layers.

Referring to FIGS. 9A to 9C, first recesses RS1 may be formed in the stack pattern STP on the first active pattern AP1. Second recesses RS2 may be formed in the stack pattern STP on the second active pattern AP2. During the formation of the first and second recesses RS1 and RS2, the device isolation layer ST may further be recessed on opposite sides of each of the first and second active patterns AP1 and AP2 (see FIG. 9C).

For example, the hardmask patterns MP and the gate spacers GS may be used as an etching mask such that the stack pattern STP on the first active pattern AP1 may be etched to form the first recesses RS1. The first recess RS1 may be formed between a pair of neighboring sacrificial patterns PP.

The active layers (see ACL of FIG. 8A) that remain after the formation of the first recesses RS1 may be referred to as first, second, and third semiconductor patterns SP1, SP2, and SP3. A first channel pattern CH1 may be constituted by the first, second, and third semiconductor patterns SP1, SP2, and SP3 between neighboring first recesses RS1.

The first recess RS1 may expose the sacrificial layers SAL. A selective etching process may be performed on the exposed sacrificial layers SAL. The etching process may include a wet etching process that selectively etches only silicon-germanium. In the etching process, each of the sacrificial layers SAL may be indented to form an indent region IDR. The indent region IDR may allow the sacrificial layer SAL to have a concave sidewall. The indent regions IDR may cause the first recess RS1 to have a wavy inner sidewall.

The second recesses RS2 in the stack pattern STP on the second active pattern AP2 may be formed by a method similar to that used for forming the first recesses RS1. The sacrificial layers SAL exposed by the second recess RS2 may undergo a selective etching process to form indent regions IDR also on the second active pattern AP2. Inner spacers ISP may be correspondingly formed in the indent regions IDR on the second active pattern AP2. A second channel pattern CH2 may be constituted by the first, second, and third semiconductor patterns SP1, SP2, and SP3 between neighboring second recesses RS2.

Referring to FIGS. 10A to 10C, first source/drain patterns SD1 may be correspondingly formed in the first recesses RS1. For example, a selective epitaxial growth (SEG) process may be performed in which an inner wall of the first recess RS1 is used as a seed layer to form an epitaxial layer that fills the first recess RS1. The epitaxial layers may be grown from seeds, or the first, second, and third semiconductor patterns SP1, SP2, and SP3, the sacrificial layers SAL, and the substrate 100 that are exposed by the first recesses RS1. For example, the SEG process may include chemical vapor deposition (CVD) or molecular beam epitaxy (MBE).

In an embodiment, the first source/drain pattern SD1 may include a semiconductor element (e.g., SiGe) whose lattice constant is greater than that of a semiconductor element of the substrate 100. During the formation of the first source/drain pattern SD1, impurities (e.g., boron, gallium, or indium) may be in-situ implanted to allow the first source/drain pattern SD1 to have p-type conductivity. Alternatively, after the formation of the first source/drain pattern SD1, impurities may be implanted into the first source/drain pattern SD1.

Second source/drain patterns SD2 may be correspondingly formed in the second recesses RS2. For example, a selective epitaxial growth (SEG) process may be performed such that an inner wall of the second recess RS2 is used as a seed to form the second source/drain pattern SD2.

In an embodiment, the second source/drain pattern SD2 may include the same semiconductor element (e.g., Si) as that of the substrate 100. During the formation of the second source/drain pattern SD2, impurities (e.g., phosphorus, arsenic, or antimony) may be in-situ implanted to allow the second source/drain pattern SD2 to have n-type conductivity. Alternatively, after the formation of the second source/drain pattern SD2, impurities may be implanted into the second source/drain pattern SD2.

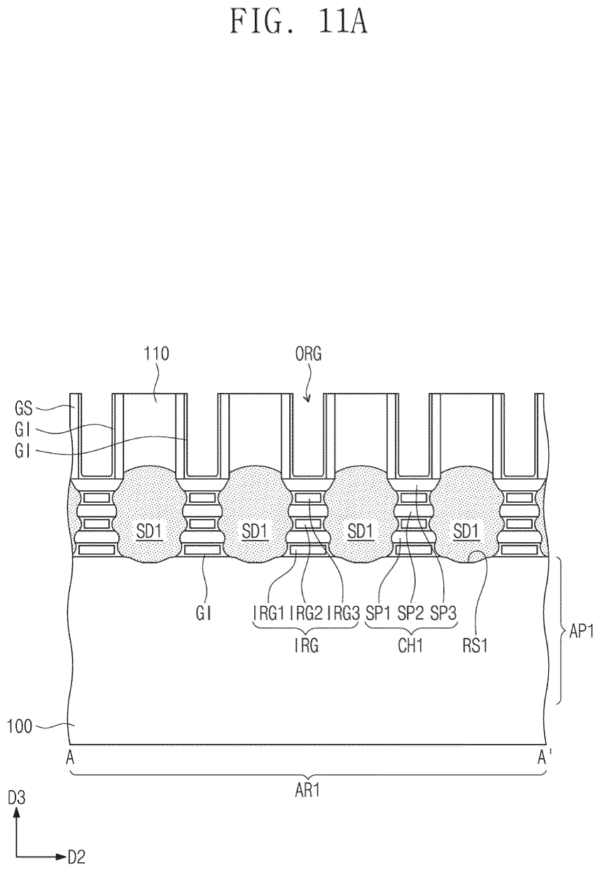

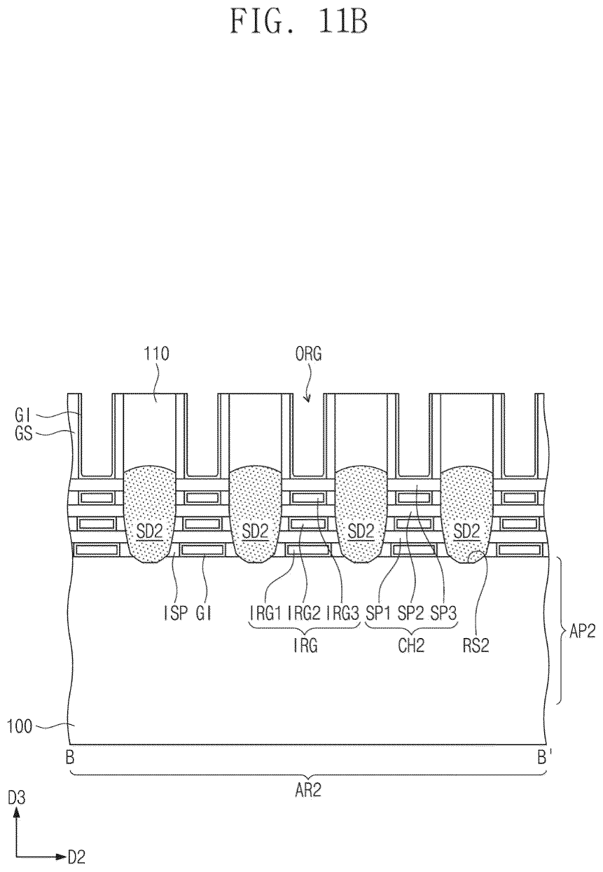

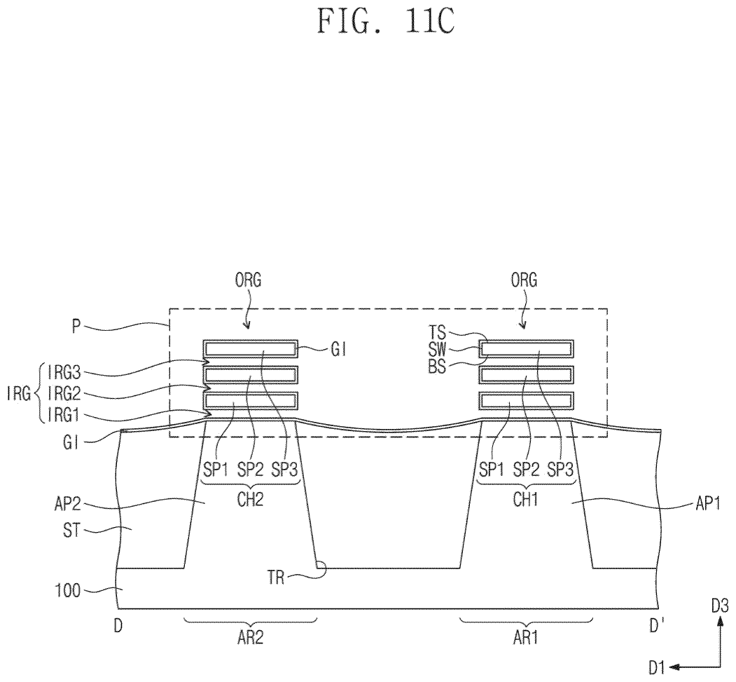

Referring to FIGS. 11A to 11C, a first interlayer dielectric layer 110 may be formed to cover the first and second source/drain patterns SD1 and SD2, the hardmask patterns MP, and the gate spacers GS. For example, the first interlayer dielectric layer 110 may include a silicon oxide layer.

The first interlayer dielectric layer 110 may be planarized until top surfaces of the sacrificial patterns PP are exposed. An etch-back or chemical mechanical polishing (CMP) process may be used to planarize the first interlayer dielectric layer 110. During the planarization process, the hardmask patterns MP may all be removed. As a result, the first interlayer dielectric layer 110 may have a top surface coplanar with those of the sacrificial patterns PP and those of the gate spacers GS.

The exposed sacrificial patterns PP may be selectively removed. The removal of the sacrificial patterns PP may form an outer region ORG that exposes the first and second channel patterns CH1 and CH2 (see FIG. 11C). The removal of the sacrificial patterns PP may include performing a wet etching process using an etchant that selectively etches polysilicon.

The sacrificial layers SAL exposed through the outer region ORG may be selectively removed to form inner regions IRG (see FIG. 11C). For example, an etching process that selectively etches the sacrificial layers SAL may be performed such that only the sacrificial layers SAL may be removed while leaving the first, second, and third semiconductor patterns SP1, SP2, and SP3. The etching process may have a high etch rate for silicon-germanium having a relatively high germanium concentration. For example, the etching process may have a high etch rate for silicon-germanium whose germanium concentration is greater than about 10 at %.

The etching process may remove the sacrificial layers SAL on the first and second active regions AR1 and AR2. The etching process may be a wet etching process. An etching material used for the etching process may promptly etch the sacrificial layer SAL whose germanium concentrate is relatively high.

Referring back to FIG. 11C, as the sacrificial layers SAL are selectively removed, only the first, second, and third semiconductor patterns SP1, SP2, and SP3 may remain on each of the first and second active patterns AP1 and AP2. The removal of the sacrificial layers SAL may form first, second, and third inner regions IRG1, IRG3, and IRG3.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring back to FIGS. 11A to 11C, a gate dielectric layer GI may be formed on the exposed first, second, and third semiconductor patterns SP1, SP2, and SP3. The gate dielectric layer GI may be formed to surround each of the first, second, and third semiconductor patterns SP1, SP2, and SP3. A gate dielectric layer GI may be formed in each of the first, second, and third inner regions IRG1, IRG2, and IRG3. A gate dielectric layer GI may be formed in the outer region ORG.

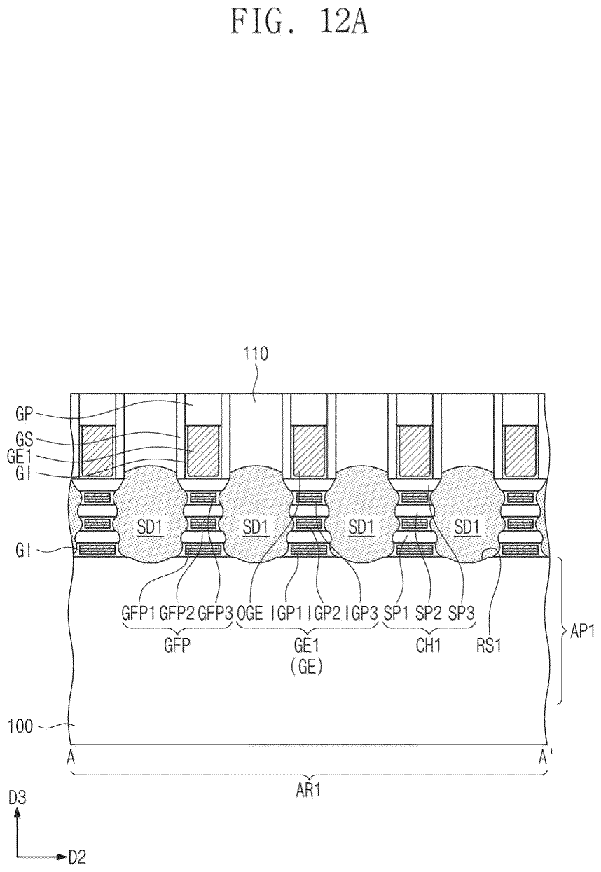

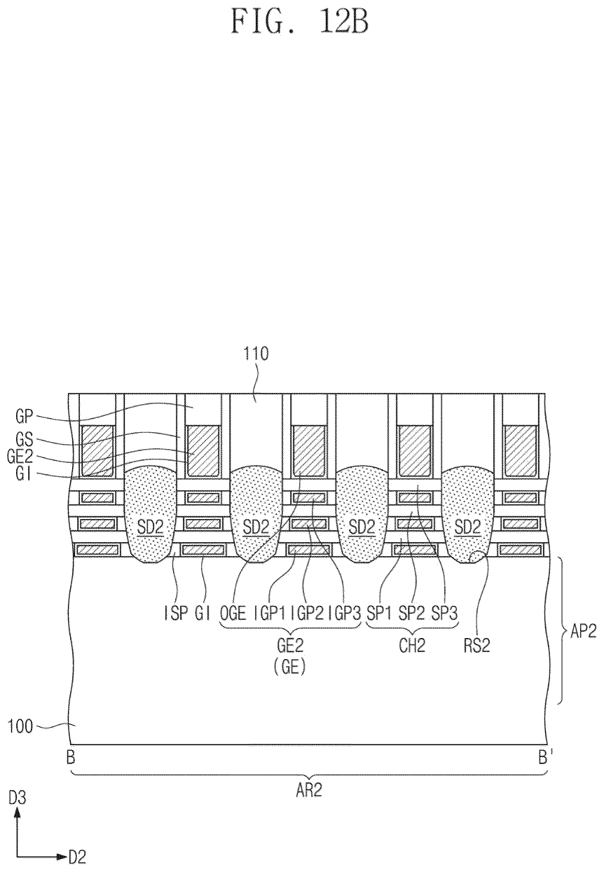

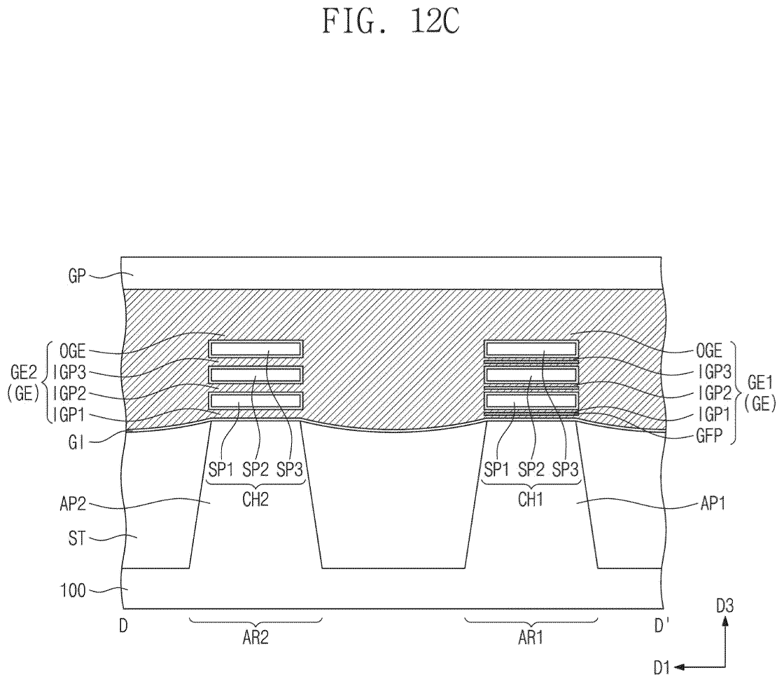

Referring to FIGS. 12A to 12C, a gate electrode GE may be formed on the gate dielectric layer GI. The formation of the gate electrode GE may include forming a first gate electrode GE1 on the first channel pattern CH1 and forming a second gate electrode GE2 on the second channel pattern CH2.

The first gate electrodes GE1 and the second gate electrode GE2 may be connected to each other to constitute one gate electrode GE. The gate electrode GE may be recessed to have a reduced height. A gate capping pattern GP may be formed on the recessed gate electrode GE.

Referring back to FIGS. 5A to 5D, a second interlayer dielectric layer 120 may be formed on the first interlayer dielectric layer 110. The second interlayer dielectric layer 120 may include a silicon oxide layer. Active contacts AC may be formed to penetrate the second interlayer dielectric layer 120 and the first interlayer dielectric layer 110 to come into electrical connection with the first and second source/drain patterns SD1 and SD2. A gate contact GC may be formed to penetrate the second interlayer dielectric layer 120 and the gate capping pattern GP to come into electrical connection with the gate electrode GE.

The formation of each of the active contact AC and the gate contact GC may include forming a barrier pattern BM and forming a conductive pattern FM on the barrier pattern BM. The barrier pattern BM may be conformally formed to include a metal layer and a metal nitride layer. The conductive pattern FM may include metal whose resistance is low.

Separation structures DB may be correspondingly formed on boundaries of a logic cell LGC. The separation structure DB may penetrate from the second interlayer dielectric layer 120 to the gate electrode GE, thereby extending into the active pattern AP1 or AP2. The separation structure DB may include a dielectric material, such as a silicon oxide layer or a silicon nitride layer.

A third interlayer dielectric layer 130 may be formed on the active contacts AC and the gate contacts GC. A first metal line M1 may be formed in the third interlayer dielectric layer 130. A fourth interlayer dielectric layer 140 may be formed on the third interlayer dielectric layer 130. A second metal line M2 may be formed in the fourth interlayer dielectric layer 140.

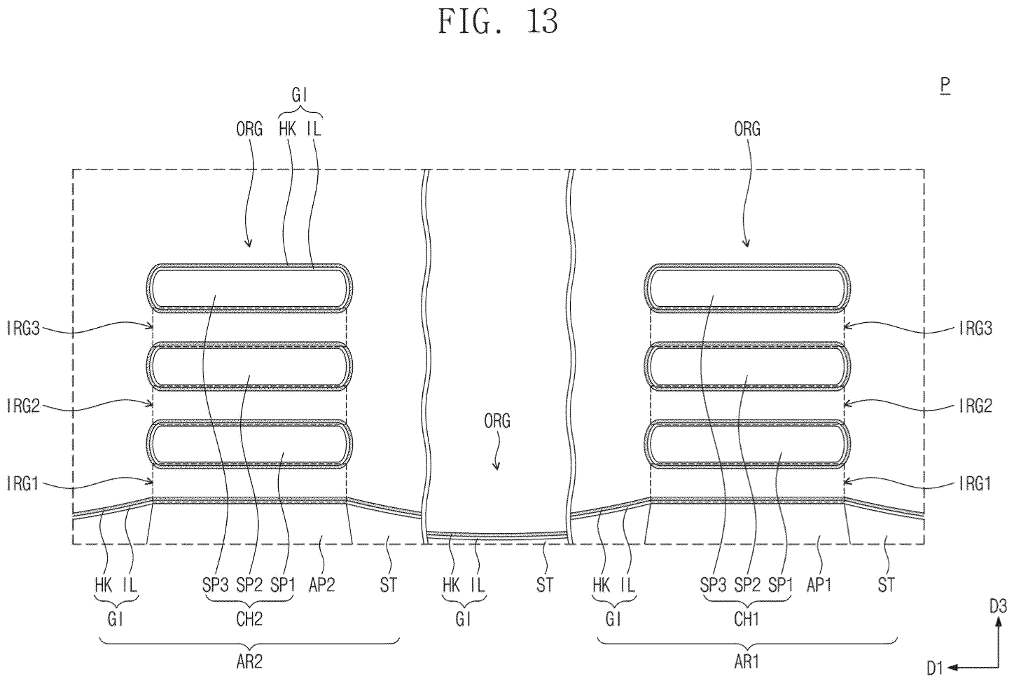

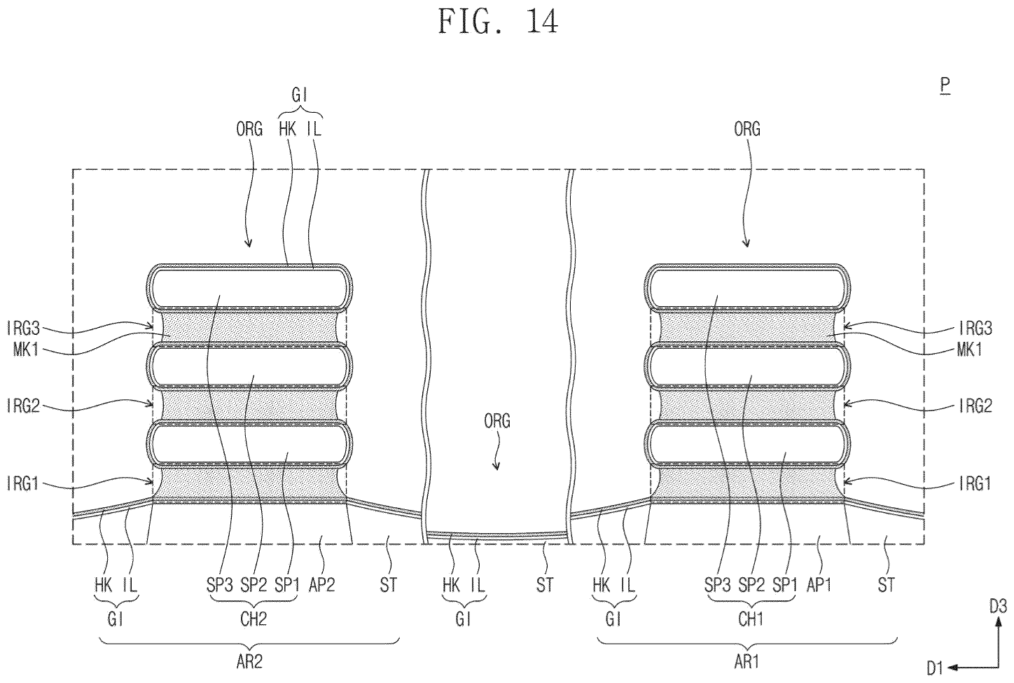

FIGS. 13 to 20 illustrate enlarged views showing a method of forming a gate electrode according to some embodiments. FIG. 13 is an enlarged cross-sectional view showing section P of FIG. 11C, and FIGS. 14 to 20 correspond to FIG. 13.

Referring to FIGS. 11C and 13, as discussed above with reference to FIGS. 11A to 11C, a gate dielectric layer GI may be formed on the first and second channel patterns CH1 and CH2. The formation of the gate dielectric layer GI may include forming an interface layer IL that directly covers a surface of each of the first and second channel patterns CH1 and CH2, and forming a high-k dielectric layer HK on the interface layer IL.

A dipole layer (see DPL of FIG. 6B) may additionally be selectively formed on the first and second channel patterns CH1 and CH2. The dipole layer DPL may be formed of oxide of a dipole element, for example, lanthanum oxide (LaO). The dipole layer DPL may undergo an annealing process to force the dipole element (e.g., La) to diffuse from the dipole layer DPL into the gate dielectric layer GI on the first and second channel patterns CH1 and CH2.

Referring to FIG. 14, on the first and second active regions AR1 and AR2, a first mask pattern MK1 may be formed in the first, second, and third inner regions IRG1, IRG2, and IRG3. For example, the formation of the first mask pattern MK1 may include coating a first mask layer on the first and second active regions AR1 and AR2, and wet-etching the first mask layer to remove the first mask layer formed on the outer region ORG.

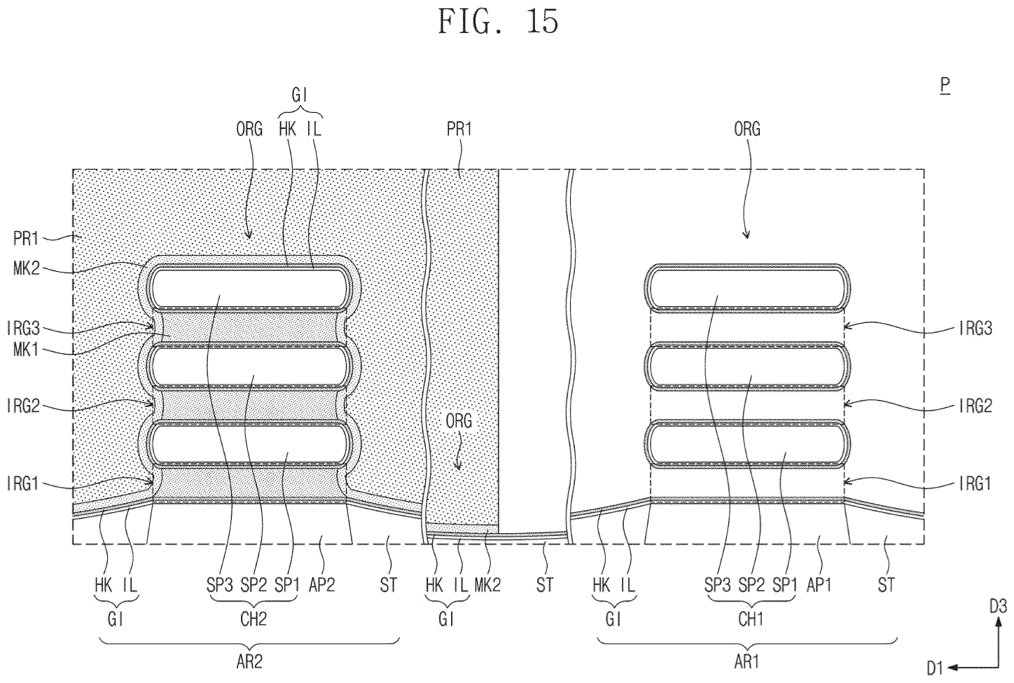

Referring to FIG. 15, a second mask layer MK2 and a first hardmask pattern PR1 may be sequentially formed. The second mask layer MK2 may be formed on the first and second active regions AR1 and AR2, and the first hardmask pattern PR1 may be formed on the second active region AR2. The first hardmask pattern PR1 may extend to a gap between the first and second active regions AR1 and AR2 that are adjacent to each other.

Afterwards, the first mask pattern MK1 and the second mask layer MK2 may be removed on the first active region AR1 which are not protected by the first hardmask pattern PR1. The removal of the first mask pattern MK1 on the first active region AR1 may expose the first, second, and third inner regions IRG1, IRG2, and IRG3 on the first active region AR1.

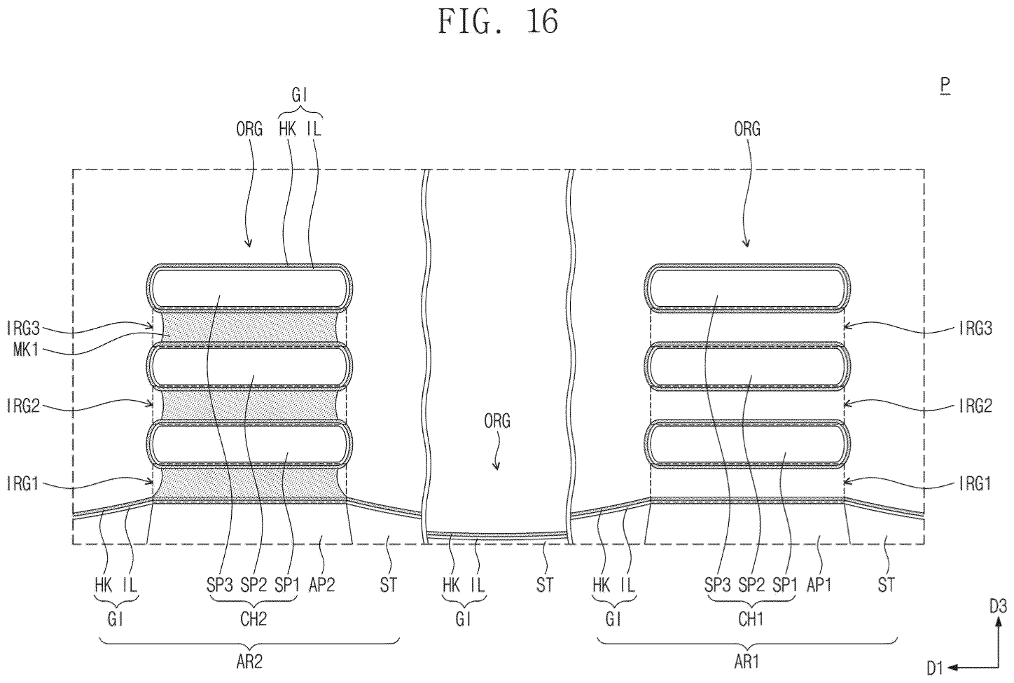

Referring to FIG. 16, the first hardmask pattern PR1 and the second mask layer MK2 may be sequentially removed from the second active region AR2. For example, the removal of the first hardmask pattern PR1 and the second mask layer MK2 may include performing an ashing process and a performing a strip process.

As the first hardmask pattern PR1 and the second mask layer MK2 are sequentially removed, a sidewall of the first mask pattern MK1 and a portion of the gate dielectric layer GI may be exposed on the second active region AR2.

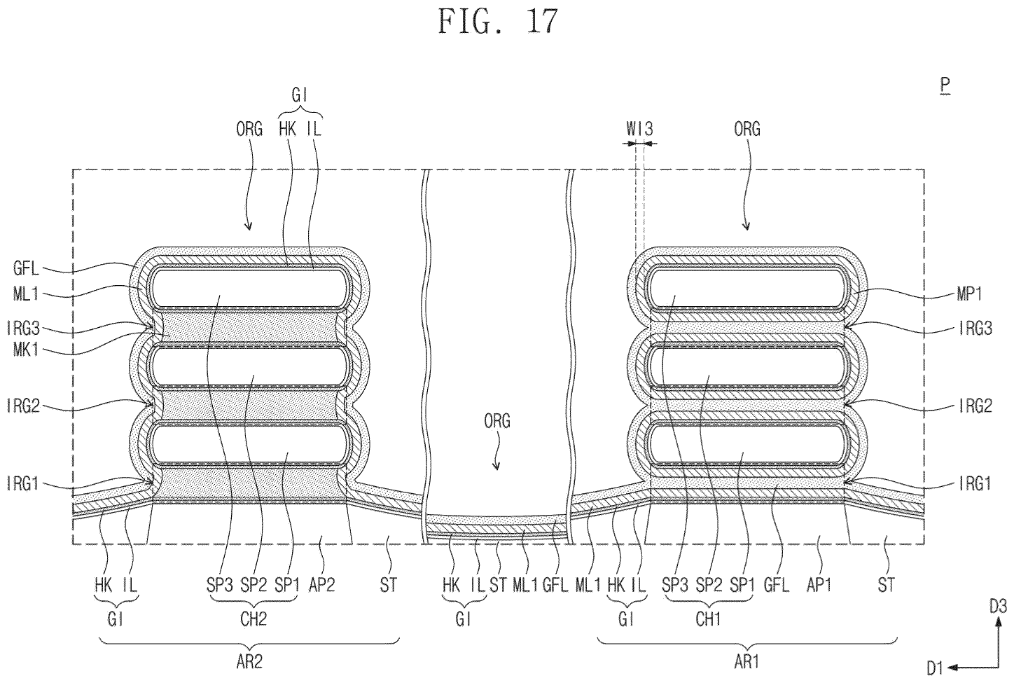

Referring to FIG. 17, a first metal layer ML1 and first metal patterns MP1 may be simultaneously formed on the first and second active regions AR1 and AR2. For example, the formation of the first metal layer ML1 and the first metal patterns MP1 may include depositing a metallic material on the first and second active regions AR1 and AR2. The first metal layer ML1 and the first metal patterns MP1 may include a first work-function metal (e.g., p-type work-function metal).

On the second active region AR2, the first metal layer ML1 may be formed to conformally cover the gate dielectric layer GI and the sidewall of the first mask pattern MK1. On the first active region AR1, the first metal patterns MP1, the first metal patterns MP1 may be formed on a top surface, a bottom surface, and opposite sidewalls of each of the first, second, and third semiconductor patterns SP1, SP2, and SP3. The first metal patterns MP1 may be spaced apart from each other in a vertical direction (e.g., a third direction D3). For example, the first metal pattern MP1 on the first semiconductor pattern SP1 may be spaced apart from the first metal pattern MP1 on the second semiconductor pattern SP2.

Thereafter, a gap-fill layer GFL may be formed on the first metal layer ML1 and the first metal patterns MP1. For example, the gap-fill layer GFL may be formed by depositing a metallic material having an etch selectivity with respect to the first metal layer ML1 and the first metal patterns MP1.

On the first active region AR1, the gap-fill layer GFL may be conformally formed on the first metal patterns MP1, and may fill between the inner regions IRG1, IRG2, and IRG3 between the first metal patterns MP1. On the second active region AR2, the gap-fill layer GFL may conformally cover the first metal layer ML1.

According to some embodiments, the first metal patterns MP1 may be formed to each have a first thickness WI3, and the first thickness WI3 may be reduced because the first metal patterns MP1 may not fill any of the inner regions IRG1, IRG2, and IRG3 on the first active region AR1.

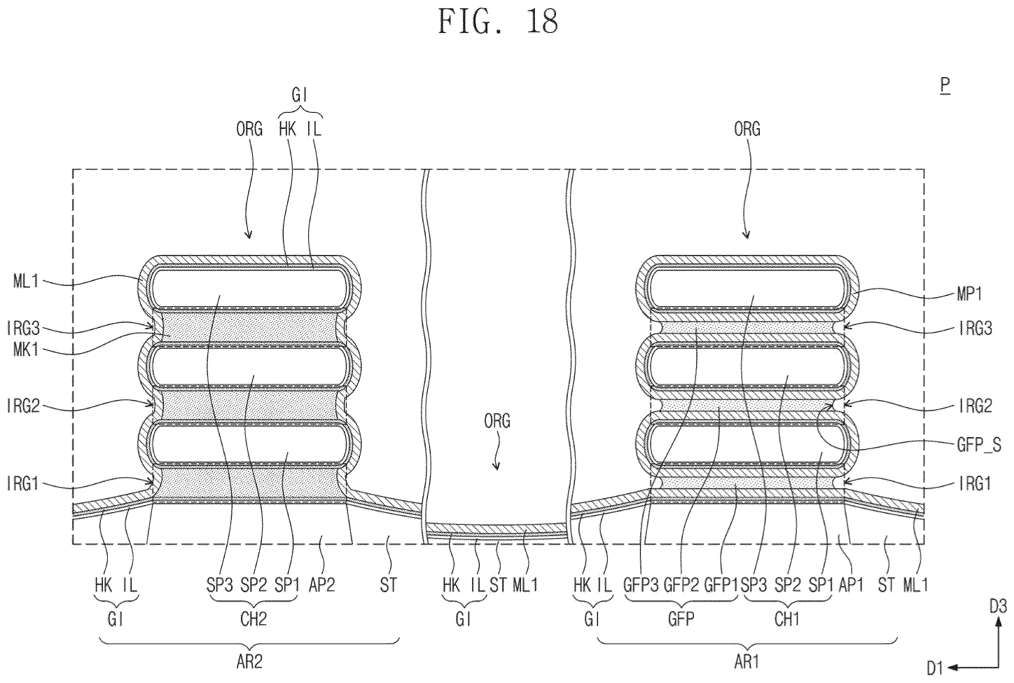

Referring to FIG. 18, a portion of the gap-fill layer GFL may be selectively removed. For example, the outer region ORG may be coated with an etchant such that the gap-fill layer GFL on the outer region ORG may be selectively removed. During the removal of the gap-fill layer GFL of the outer region ORG, the gap-fill layer (see GFL of FIG. 17) may not be removed in the inner regions IRG1, IRG2, and IRG3 on the first active region AR1. On the first active region AR1, gap-fill patterns GFP may be defined to refer to the gap-fill layers (see GFL of FIG. 17) that remain in the regions IRG1, IRG2, and IRG3. On the second active region AR2, the gap-fill layer (see GFL of FIG. 17) may all be removed.

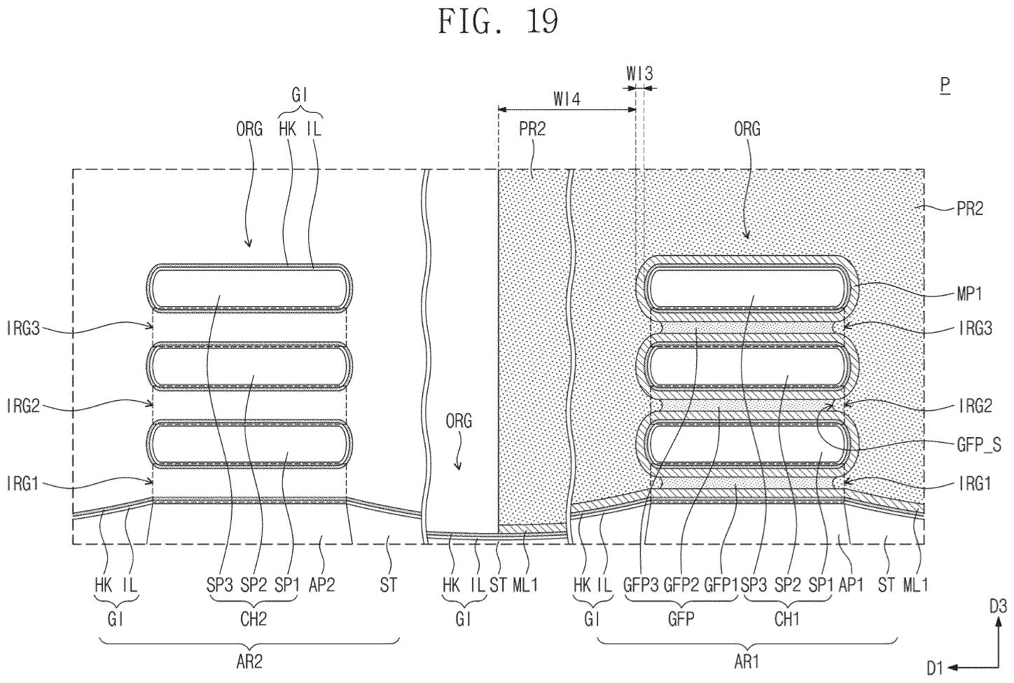

Referring to FIG. 19, a second hardmask pattern PR2 may be formed on the first active region AR1. The second hardmask pattern PR2 may extend in the first direction D1 on the first active region AR1, and may reside onto a section between the first and second active regions AR1 and AR2.

A patterning using the second hardmask pattern PR2 may be performed to remove the first metal layer (see ML1 of FIG. 18) and the first mask pattern MK1 on the second active region AR2. As the first mask pattern MK1 is removed, the inner regions IRG1, IRG2, and IRG3 may be exposed on the second active region AR2. A minimum distance WI4 from a sidewall of the first metal pattern MP1 may be required to perform the patterning through the second hardmask pattern PR2.

According to some embodiments, the first thickness WI3 of the first metal pattern MP1 may be formed small. For example, as the first thickness WI3 of the first metal pattern MP1 is formed small, it may be possible to expand, or widen, a section which remains open without the placement of the second hardmask pattern PR2 and to secure a margin of a section for patterning. It may thus be possible to reduce damage to semiconductor devices on the second active region AR2 and to provide semiconductor devices with improved reliability and electrical properties.

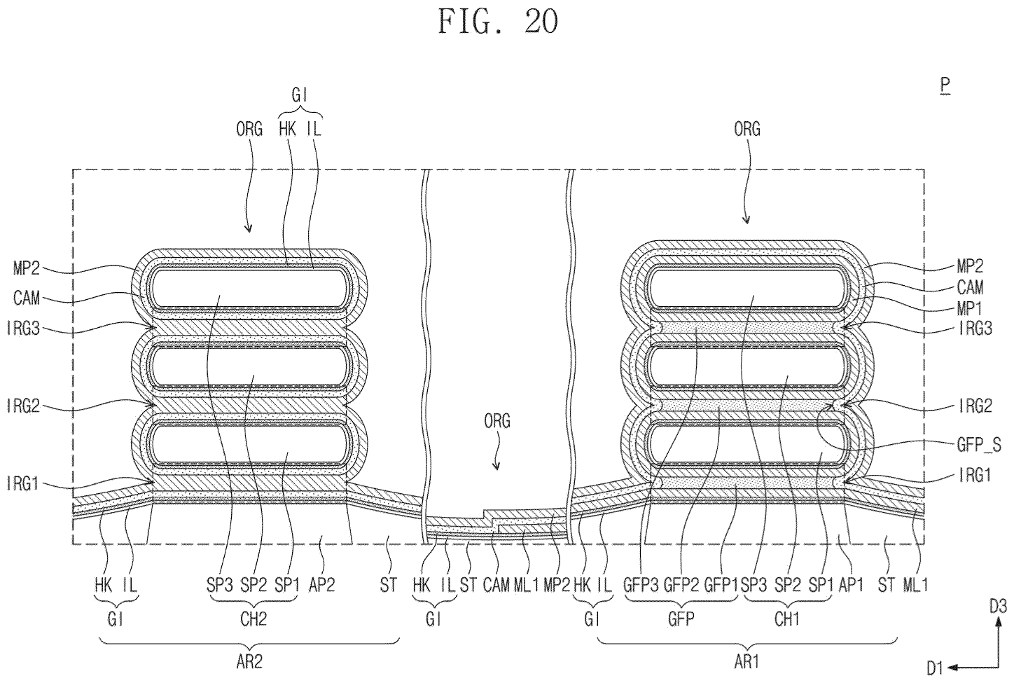

Referring to FIG. 20, a capping pattern CAM may be formed on the first metal patterns MP1 and the first, second, and third semiconductor patterns SP1, SP2, and SP3 of the second channel patterns CH2. The capping pattern CAM may contact the gate dielectric layer GI on the second active region AR2 and may cover the first metal patterns MP1 and the gap-fill patterns GFP on the first active region AR1.

Thereafter, a second metal pattern MP2 may be formed on the capping pattern CAM. The second metal pattern MP2 may fill the first, second, and third inner regions IRG1, IRG2, and IRG3 on the second active region AR2. The second metal pattern MP2 may include a second work-function metal (e.g., n-type work-function metal).

Referring back to FIG. 6A, a filling metal pattern FMP may be formed on the second metal pattern MP2. The filling metal pattern FMP may fill the outer region ORG.

In a semiconductor device, a first active region may be provided thereon with a first metal pattern and a second metal pattern whose compositions are different from each other, and the first metal pattern and the second metal pattern may have different work functions from each other, and thus it may be possible to implement transistors having different threshold voltages from each other.

Moreover, the first metal patterns may be formed with their overall small thicknesses that cover semiconductor patterns on the first active region, and inner regions between vertically spaced semiconductor patterns (or between the first metal patterns) may be filled with gap-fill patterns. The small thicknesses of the first metal patterns may cause an increase in horizontal distance between the first metal patterns and the second active region which is horizontally adjacent to the first active region. Therefore, on the second active region, it may be possible to secure a margin of a section for patterning. Accordingly, damage to semiconductor devices may be reduced when a gate is opened on the second active region, and semiconductor devices may improve in reliability and electrical properties.

While aspects of embodiments have been particularly shown and described, it will be understood that various changes in form and details may be made therein without departing from the spirit and scope of the following claims.

What is claimed is:

1. A semiconductor device, comprising:
a first active pattern on a first active region of a substrate;
a second active pattern on a second active region of the substrate, wherein the first active region is spaced apart from the second active region in a first direction;
a first channel pattern that comprises a plurality of first semiconductor patterns that are spaced apart from each other and vertically stacked on the first active pattern; and
a gate electrode on the first channel pattern,
wherein the gate electrode comprises:
a plurality of first metal patterns on the plurality of first semiconductor patterns on the first active region; and
a gap-fill pattern between the plurality of first metal patterns on the first active region, and
wherein a maximum width in the first direction of the gap-fill pattern is less than a maximum width in the first direction of the plurality of first metal patterns.

2. The semiconductor device of claim 1, wherein the gap-fill pattern has a rounded sidewall.

3. The semiconductor device of claim 1, wherein the gap-fill pattern comprises at least one selected from metal nitride, metal oxynitride, metal oxycarbide, and metal oxynitride carbide.

4. The semiconductor device of claim 1, wherein the plurality of first metal patterns are spaced apart from each other in a vertical direction.

5. The semiconductor device of claim 1, wherein the gap-fill pattern has an etch selectivity with respect to the plurality of first metal patterns.

6. The semiconductor device of claim 1, wherein the plurality of first metal patterns are provided on a top surface, a bottom surface, and opposite sidewalls of each of the plurality of first semiconductor patterns.

7. The semiconductor device of claim 1, further comprising a second channel pattern that comprises a plurality of second semiconductor patterns that are spaced apart from each other and vertically stacked on the second active pattern,
wherein the gate electrode further comprises:
a second metal pattern that covers sidewalls of the plurality of first metal patterns on the first active region and covers sidewalls of the plurality of second semiconductor patterns on the second active region; and
a filling metal pattern on the second metal pattern.

8. The semiconductor device of claim 7, wherein the plurality of first metal patterns and the second metal pattern comprise aluminum (Al), and
wherein an aluminum concentration of the second metal pattern is different from an aluminum concentration of the plurality of first metal patterns.

9. The semiconductor device of claim 7, wherein a work function of the plurality of first metal patterns is different from a work function of the second metal pattern.

10. The semiconductor device of claim 7, wherein the gate electrode further comprises a capping pattern on the first active region that extends between the plurality of first metal patterns and the second metal pattern, and
wherein the capping pattern is in contact with the sidewalls of the plurality of first metal patterns and a sidewall of the gap-fill pattern.

11. The semiconductor device of claim 7, further comprising a gate dielectric layer that extends between the gate electrode and the first channel pattern and between the gate electrode and the second channel pattern,
wherein, on the first active region, the plurality of first metal patterns are in contact with the gate dielectric layer, and
wherein, on the second active region, the second metal pattern is in contact with the gate dielectric layer.

12. A semiconductor device, comprising:
a first active pattern on a first active region of a substrate;
a second active pattern on a second active region of the substrate, wherein the first active region is spaced apart from the second active region in a first direction;
a first channel pattern comprising a plurality of first semiconductor patterns that are spaced apart from each other and vertically stacked on the first active pattern;
a second channel pattern that comprises a plurality of second semiconductor patterns that are spaced apart from each other and vertically stacked on the second active pattern; and
a gate electrode on the first channel pattern and the second channel pattern,
wherein the gate electrode comprises:
a plurality of first metal patterns on the first active region, the plurality of first metal patterns being on the plurality of first semiconductor patterns and spaced apart from each other in a vertical direction;
a plurality of gap-fill patterns in first inner regions between the plurality of first metal patterns on the first active region; and
a second metal pattern that covers sidewalls of the plurality of first metal patterns on the first active region and is in second inner regions between the plurality of second semiconductor patterns on the second active region.

13. The semiconductor device of claim 12, wherein each of the plurality of gap-fill patterns has a rounded sidewall.

14. The semiconductor device of claim 12, further comprising a gate dielectric layer between the gate electrode and the plurality of first semiconductor patterns, and between the gate electrode and the plurality of second semiconductor patterns,
wherein, on the first active region, the plurality of first metal patterns are in contact with the gate dielectric layer, and
wherein, on the second active region, the second metal pattern is in contact with the gate dielectric layer.

15. The semiconductor device of claim 12, wherein a work function of the plurality of first metal patterns is different from a work function of the second metal pattern.

16. The semiconductor device of claim 12, wherein the plurality of gap-fill patterns have an etch selectivity with respect to the plurality of first metal patterns.

17. The semiconductor device of claim 12, wherein the gate electrode further comprises a capping pattern on the first active region, and between the plurality of first metal patterns and the second metal pattern, and
wherein the capping pattern is in contact with the sidewalls of the plurality of first metal patterns and sidewalls of the plurality of gap-fill patterns.

18. The semiconductor device of claim 12, wherein the plurality of first metal patterns and the second metal pattern comprise aluminum, and
wherein an aluminum concentration of the second metal pattern is different from an aluminum concentration of the plurality of first metal patterns.

19. A semiconductor device, comprising:
a first active pattern on a first active region of a substrate;
a second active pattern on a second active region of the substrate, wherein the first active region is spaced apart from the second active region in a first direction;
a device isolation layer that fills a trench that defines the first active pattern and the second active pattern;
a first channel pattern that comprises a plurality of first semiconductor patterns that are spaced apart from each other and vertically stacked on the first active pattern;
a second channel pattern that comprises a plurality of second semiconductor patterns that are spaced apart from each other and vertically stacked on the second active pattern;
a first gate electrode on the first channel pattern;
a second gate electrode on the second channel pattern;
a first interlayer dielectric layer on the first gate electrode and the second gate electrode; and
a plurality of gate contacts that penetrate the first interlayer dielectric layer and contact the first gate electrode and the second gate electrode,
wherein the first gate electrode comprises:
a plurality of first metal patterns on the plurality of first semiconductor patterns on the first active region; and
a gap-fill pattern between the plurality of first metal patterns on the first active region, and
wherein a maximum width in the first direction of the gap-fill pattern is less than a maximum width in the first direction of the plurality of first metal patterns.

20. The semiconductor device of claim 19, wherein, on the second active region, the second gate electrode comprises a second metal pattern on each of the plurality of second semiconductor patterns, and
wherein a work function of the second metal pattern is different from a work function of the plurality of first metal patterns.
